(19) United States
(12) Patent Application Publication
(10) Pub. No.: US 2022/0243001 A1
(43) Pub. Date: Aug. 4, 2022

(54) EPOXY RESIN COMPOSITION

(71) Applicant: SUMITOMO SEIKA CHEMICALS CO., LTD., Kako-gun, Hyogo (JP)

(72) Inventors: Ryota HARISAKI, Kako-gun (JP); Katsumasa YAMAMOTO, Kako-gun (JP)

(73) Assignee: SUMITOMO SEIKA CHEMICALS CO., LTD., Kako-gun, Hyogo (JP)

(21) Appl. No.: 17/597,063

(22) PCT Filed: Jun. 15, 2020
(86) PCT No.: PCT/JP2020/023355

§ 371 Date: Dec. 23, 2021

(30) Foreign Application Priority Data
Jun. 27, 2019 (JP) 2019-119995

(51) Int. Cl. C08G 59/30; C08G 59/62; C08K 3/22; C08K 3/36; H01L 23/29

(52) U.S. Cl. CPC C08G 59/306; C08G 59/621; C08K 2003/2227; C08K 3/36; H01L 23/295; C08K 3/22

(57) ABSTRACT

Provided is an epoxy resin composition that gives a cured product having excellent adhesion to metal and low dielectric characteristics, and that has good workability during use and high storage stability. Specifically, provided is an epoxy resin composition comprising a specific epoxy resin and a specific phenol-based curing agent.

### TECHNICAL FIELD

The present invention relates to an epoxy resin composition, a cured product obtained by using the same, use of the composition, etc.

### BACKGROUND ART

Epoxy resin compositions are widely used in various industrial fields, such as paints, adhesives, and electrical and electronic because cured products obtained from them have excellent adhesion, corrosion resistance, electrical characteristics, and the like. Among these, in the field of electronic materials, such as semiconductors and printed circuit boards, epoxy resin compositions are used as sealing materials, printed circuit board materials, etc. With the technological innovation in these fields, the demand for higher performance is increasing.

Conventionally, epoxy resin compositions containing a bisphenol epoxy resin or a cresol novolak epoxy resin, a phenol novolak resin, and a curing accelerator have mainly been used as resin compositions for semiconductor sealing materials and resin compositions for printed circuit boards because their cured products have excellent heat resistance and excellent adhesion to metal used in wiring. However, many phenol novolak resins were generally solid, and some of them had inferior workability. Further, since the reaction between the bisphenol epoxy resin and the phenol novolak resin gradually proceeded during storage, there were problems that the storage stability was poor and cured products of the resin compositions containing a bisphenol epoxy resin and a phenol novolak resin had high relative dielectric constant and dielectric loss tangent.

Particularly in semiconductors, with the miniaturization of electronic devices, the miniaturization and thinning of semiconductor packages are progressing rapidly. Adopting surface-mounted packages such as BGA and CSP that can be mounted at a high density has become mainstream. This has led to ever higher demands on the performance of resin compositions for semiconductor sealing materials.

In addition, signal speed and frequency are increasing in communication equipment, and reducing the transmission loss is required. Since the transmission loss depends on the relative dielectric constant and dielectric loss tangent of electronic component constituent materials, it is effective to reduce their relative dielectric constant and dielectric loss tangent. Therefore, low dielectric characteristics (low relative dielectric constant and low dielectric loss tangent) are strongly required particularly for resin compositions for sealing materials of semiconductors for communication equipment and resin compositions for printed circuit boards.

### CITATION LIST

### Patent Literature

PTL 1: JP2003-160644A
PTL 2: JPH05-9270A
PTL 3: JP2004-27159A
PTL 4: WO2018/131567

### SUMMARY OF INVENTION

### Technical Problem

PTL 1 proposes an epoxy resin composition to which a thiadiazole compound is added to improve the adhesion to metal, and in which a liquid phenol novolak resin is mixed. However, no reference is made to the relative dielectric constant and dielectric loss tangent of cured products of the composition.

PTL 2 proposes an epoxy resin composition mixed with hollow silica to reduce the relative dielectric constant.

PTL 3 proposes an epoxy resin composition mixed with a liquid phenol novolak resin, to which an organic acid is added to improve the storage stability, and in which the viscosity is reduced to improve workability.

However, there has still been a demand for epoxy resin compositions that give cured products having excellent adhesion to metal and low dielectric characteristics, and that have good workability during use and high storage stability.

### Solution to Problem

As a result of extensive research, the present inventors found that an epoxy resin composition comprising a specific epoxy resin containing a silicon atom and a phenol-based curing agent that is liquid at 25° C. has good workability during use and high storage stability, and gives a cured product having excellent adhesion and low dielectric characteristics. The present invention has been completed upon further studies based on this finding.

The present invention includes, for example, the main subjects described in the following items.

Item 1. An epoxy resin composition comprising an epoxy resin and a phenol-based curing agent that is liquid at 25° C., the epoxy resin being at least one member selected from the group consisting of:

an epoxy resin represented by the formula (1-iia):

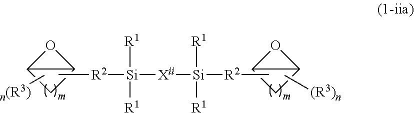

wherein Xⁱⁱ is a divalent group obtained by removing two hydrogen atoms from a saturated hydrocarbon ring or an unsaturated hydrocarbon ring, or from rings having a structure in which 2 to 6 saturated hydrocarbon rings and/or unsaturated hydrocarbon rings are condensed; or a divalent group represented by the formula (2^{g}-iia):

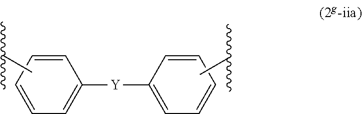

wherein Y is a bond, a C₁₋₆ alkylene group that may be substituted with a C₁₋₄ alkyl group, an oxygen atom (—O—), a sulfur atom (—S—), —SO—, or —SO₂—;

R¹ is the same or different, and is a C₁₋₁₈ alkyl group, a C₂₋₉ alkenyl group, a cycloalkyl group, an aryl group, or an aralkyl group, wherein one or more carbon atoms of these groups may be replaced by at least one atom selected from the group consisting of an oxygen atom and a nitrogen atom;

R² is the same or different, and is a C₁₋₁₈ alkylene group, wherein one or more carbon atoms of this group other than a carbon atom directly bonded to a silicon atom may be replaced by at least one atom selected from the group consisting of an oxygen atom and a nitrogen atom;

R³ is the same or different, and is a C₁₋₁₈ alkyl group, a C₂₋₉ alkenyl group, a cycloalkyl group, an aryl group, or an aralkyl group, wherein one or more carbon atoms of these groups may be replaced by at least one atom selected from the group consisting of an oxygen atom and a nitrogen atom;

m is an integer of 0 to 6; and

n is an integer of 0 to 3;

an epoxy resin represented by the formula (1-iiia):

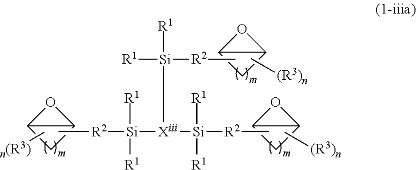

wherein Xⁱⁱⁱ is a trivalent group obtained by removing three hydrogen atoms from a saturated hydrocarbon ring or an unsaturated hydrocarbon ring, or from rings having a structure in which 2 to 6 saturated hydrocarbon rings and/or unsaturated hydrocarbon rings are condensed; or a trivalent group represented by the formula (2^{g}-iiia):

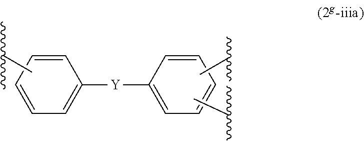

wherein Y is as defined above; and

R², R³, m, and n are as defined above; and an epoxy resin represented by the formula (1-iva):

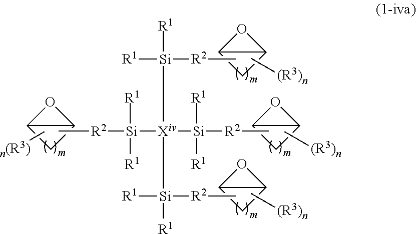

wherein X^{iv} is a tetravalent group obtained by removing four hydrogen atoms from a saturated hydrocarbon ring or an unsaturated hydrocarbon ring, or from rings having a structure in which 2 to 6 saturated hydrocarbon rings and/or unsaturated hydrocarbon rings are condensed; or a tetravalent group represented by the formula (2^{g}):

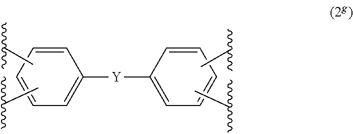

wherein Y is as defined above; and

R¹, R², R³, m, and n are as defined above.

Item 2. The epoxy resin composition according to Item 1, wherein the saturated hydrocarbon ring is a C₄₋₈ saturated hydrocarbon ring, and the unsaturated hydrocarbon ring is a C₄₋₈ unsaturated hydrocarbon ring.

Item 3. The epoxy resin composition according to Item 1 or 2, wherein the epoxy resin is at least one member selected from the group consisting of:

an epoxy resin represented by the formula (1-IIa):

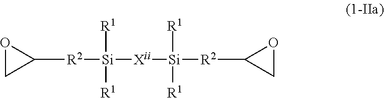

wherein R¹, R², and Xⁱⁱ are as defined above;
an epoxy resin represented by the formula (1-IIb):

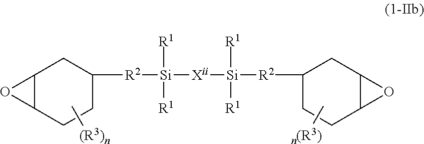

wherein R¹, R², R³, Xⁱⁱ, and n are as defined above; and
an epoxy resin represented by the formula (1-IIIa):

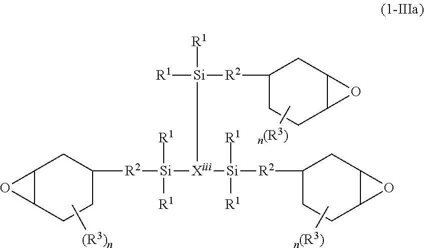

wherein R¹, R², R³, Xⁱⁱⁱ, and n are as defined above.

Item 4. The epoxy resin composition according Item 3, wherein the epoxy resin represented by the formula (1-IIa) is an epoxy resin wherein Xⁱⁱ is a 1,4-phenylene group or a group represented by the formula (2^{g}-iia′):

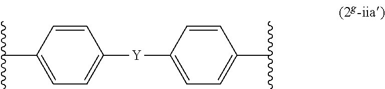

wherein Y is as defined above,

R¹ is the same or different, and is a C₁₋₃ alkyl group, and R² is the same or different, and is a C₂₋₆ alkylene group, (*)—(CH₂)₂—O—CH₂—, (*)—(CH₂)₃—O—CH₂—, (*)—(CH₂)₃—O—(CH₂)₂—, or (*)—(CH₂)₅—O—(CH₂)₄—, provided that (*) represents the side of R² binding to the silicon atom;

the epoxy resin represented by the formula (1-IIb) is an epoxy resin wherein Xⁱⁱ is a 1,4-phenylene group or a group represented by the formula (2^{g}-iia′):

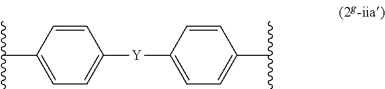

wherein Y is as defined above,

R¹ is the same or different, and is a C₁₋₃ alkyl group, both n is 0, and R² is the same or different, and is a C₂₋₆ alkylene group; and

the epoxy resin represented by the formula (1-IIIa) is an epoxy resin wherein Xⁱⁱⁱ is

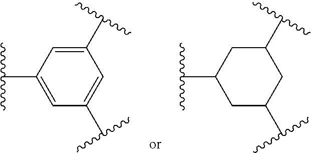 [SMILES: *c1cc(*)cc(*)c1 ; *C1CC(*)CC(*)C1]

or a group represented by the formula (2^{g}-iiia′):

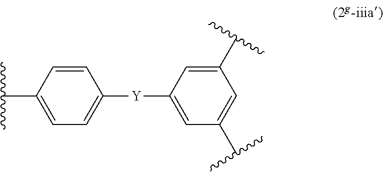

wherein Y is as defined above,

R¹ is the same or different, and is a C₁₋₃ alkyl group, both n is 0, and R² is the same or different, and is a C₂₋₆ alkylene group.

Item 5. The epoxy resin composition according any one of Items 1 to 4, wherein the phenol-based curing agent that is liquid at 25° C. comprises at least one member selected from the group consisting of liquid allylphenol resins, liquid propenylphenol resins, and liquid alkylphenol resins.

Item 6. The epoxy resin composition according any one of Items 1 to 5, wherein the phenol-based curing agent that is liquid at 25° C. comprises at least one member selected from the group consisting of resins represented by the formula (7):

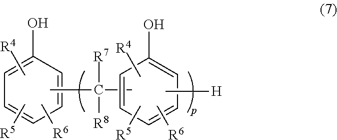

wherein R⁴ to R⁶ are the same or different, and each is a hydrogen atom, a C₂₋₉ alkenyl group, a C₁₋₁₈ alkyl group, or a C₁₋₉ alkylol group; R⁷ and R⁸ are the same or different, and each is a hydrogen atom or a C₁₋₄ alkyl group; and p is an average value of 0 to 6; provided that not all of R⁴ are hydrogen atoms, not all of R⁵ are hydrogen atoms, and not all of R⁶ are hydrogen atom.

Item 7. The epoxy resin composition according any one of Items 1 to 6, further comprising at least one of silica and alumina as an inorganic filler.

Item 8. A varnish comprising the epoxy resin composition according to any one of Items 1 to 7 and an organic solvent.

Item 9. A cured product of the epoxy resin composition according to any one of Items 1 to 7.

Item 10. A semiconductor sealing body, a semiconductor sealing material, a liquid sealing material, an underfill material, a potting material, a sealing material, an interlayer insulation film, an adhesive layer, a coverlay film, an electromagnetic shielding film, a printed circuit board material, or a composite material, each of which comprises the epoxy resin composition according to any one of Items 1 to 7, the varnish according to Item 8, or the cured product according to Item 9.

Item 11. The epoxy resin composition according to any one of Items 1 to 7, the varnish according to Item 8, or the cured product according to Item 9, for a semiconductor sealing body, a semiconductor sealing material, a liquid sealing material, an underfill material, a potting material, a sealing material, an interlayer insulation film, an adhesive layer, a coverlay film, an electromagnetic shielding film, a printed circuit board material, or a composite material.

Item 12. Use of the epoxy resin composition according to any one of Items 1 to 7, the varnish according to Item 8, or the cured product according to Item 9, for producing a semiconductor sealing body, a semiconductor sealing material, a liquid sealing material, an underfill material, a potting material, a sealing material, an interlayer insulation film, an adhesive layer, a coverlay film, an electromagnetic shielding film, a printed circuit board material, or a composite material.

### Advantageous Effects of Invention

Provided is an epoxy resin composition that has good workability during use and high storage stability, and that gives a cured product having excellent adhesion to metal and low dielectric characteristics. The epoxy resin composition can be suitably used, for example, for semiconductor sealing bodies, semiconductor sealing materials, liquid sealing materials, underfill materials, potting materials, sealing materials, interlayer insulation films, adhesive layers, coverlay films, electromagnetic shielding films, printed circuit board materials, composite materials, or the like.

### DESCRIPTION OF EMBODIMENTS

The epoxy resin composition included in the present invention comprises an epoxy resin and a specific phenol-based curing agent, the epoxy resin being represented by the formula (1):

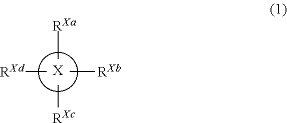

The epoxy resin composition is also referred to as “the epoxy resin composition of the present invention.”

In the formula (1), R^{Xa}, R^{Xb}, R^{Xc} and R^{Xd} are the same or different, and each is a hydrogen atom, a lower alkyl group, a lower alkoxy group, a lower alkenyl group, a halogen atom, or a group represented by the formula (3):

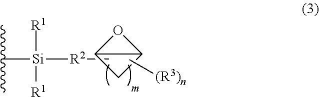

(hereinafter also referred to as the “group of the formula (3)”). Hereinafter, a lower alkyl group, a lower alkoxy group, and a lower alkenyl group are also collectively referred to as “lower carbon substituents.” In the present invention, among the lower carbon substituents, a lower alkyl group or a lower alkoxy group is more preferable.

However, at least one of R^{Xa}, R^{Xb}, R^{Xc}, and R^{Xd} is a group of the formula (3). In other words, three of R^{Xa}, R^{Xb}, R^{Xc}, and R^{Xd} are hydrogen atoms, halogen atoms, or lower carbon substituents, and the other one is a group of the formula (3); two of them are hydrogen atoms, halogen atoms, or lower carbon substituents, and the other two are groups of the formula (3); one of them is a hydrogen atom, a halogen atom, or a lower carbon substituent, and the other three are groups of the formula (3); or all of them are groups of the formula (3). More specifically, for example, R^{Xa} R^{Xb}, R^{Xc}, and R^{Xd} may be as follows:

(i) R^{Xa}, R^{Xb} and R^{Xc} are hydrogen atoms, halogen atoms, or lower carbon substituents, and R^{Xd} is a group of the formula (3);
(ii) R^{Xa} and R^{Xb} are hydrogen atoms, halogen atoms, or lower carbon substituents, and R^{Xc} and R^{Xd} are groups of the formula (3);
(iii) R^{Xa} is a hydrogen atom, a halogen atom, or a lower carbon substituent, and R^{Xb} R^{Xc} and R^{Xd} are groups of the formula (3); or
(iv) all of R^{Xa}, R^{Xb}, R^{Xc}, and R^{Xd} are groups of the formula (3). Of R^{Xa} R^{Xb}, R^{Xc}, and R^{Xd}, one or more members that are not groups of the formula (3) are more preferably hydrogen atoms or lower carbon substituents.

In the formula (1), R^{Xa}, R^{Xb}, R^{Xc} and R^{Xd} may be the same or different. Therefore, (i) when R^{Xa}, R^{Xb}, and R^{Xc} are hydrogen atoms, halogen atoms, or lower carbon substituents, and when R^{Xd} is a group of the formula (3), R^{Xa}, R^{Xb}, and R^{Xc} may be the same or different. (ii) When R^{Xa} and R^{Xb} are hydrogen atoms, halogen atoms, or lower carbon substituents, and when R^{Xc} and R^{Xd} are groups of the formula (3), R^{Xa} and R^{Xb} may be the same or different, and R^{Xc} and R^{Xd} may also be the same or different. (iii) When R^{Xa} is a hydrogen atom, a halogen atom, or a lower carbon substituent, and when R^{Xb}, R^{Xc}, and R^{Xd} are groups of the formula (3), R^{Xb}, R^{Xc}, and R^{Xd} may be the same or different. (iv) When all of R^{Xa}, R^{Xb}, R^{Xc}, and R^{Xd} are groups of the formula (3) R^{Xa}, R^{Xb}, R^{Xc} and R^{Xd} may be the same or different. In any of these cases, the groups of the formula (3) are preferably the same.

Moreover, when two or three of R^{Xa}, R^{Xb}, R^{Xc}, and R^{Xd} are halogen atoms or lower carbon substituents, these halogen atoms or lower carbon substituents may also be the same or different. In this case, two or three of R^{Xa}, R^{Xb}, R^{Xc}, and R^{Xd} are more preferably the same lower carbon substituents.

In the present specification, the lower carbon substituent refers to a lower alkyl group, a lower alkoxy group, or a lower alkenyl group. The term “lower” used herein means 1 to 6 (1, 2, 3, 4, 5, or 6) carbon atoms. Of the lower carbon substituents, a lower alkyl group or a lower alkoxy group is preferable. Specifically, preferable examples of lower alkyl groups include a methyl group, an ethyl group, an n-propyl group, an isopropyl group, an n-butyl group, an isobutyl group, and the like. Preferable examples of lower alkoxy groups include a methoxy group, an ethoxy group, a propoxy group, an isopropoxy group, a butoxy group, an isobutoxy group, and the like.

Moreover, in the present specification, the halogen atom is a fluorine atom, a chlorine atom, a bromine atom, or an iodine atom; preferably a fluorine atom, a chlorine atom, or a bromine atom; and more preferably a fluorine atom or a bromine atom.

In the formula (1), X ring is a saturated hydrocarbon ring or an unsaturated hydrocarbon ring, or rings having a structure in which 2 to 6 saturated hydrocarbon rings and/or unsaturated hydrocarbon rings are condensed, or in which 2 saturated hydrocarbon rings and/or unsaturated hydrocarbon rings are connected. In the present specification, the saturated hydrocarbon ring is, for example, preferably a C₄₋₈ (4, 5, 6, 7, or 8) saturated hydrocarbon ring, and particularly preferably a cyclopentane ring, a cyclohexane ring, or the like. In the present specification, the unsaturated hydrocarbon ring is, for example, preferably a C₄₋₈ (4, 5, 6, 7, or 8) unsaturated hydrocarbon ring, and particularly preferably a benzene ring or the like. In the present specification, the rings having a structure in which 2 to 6 saturated hydrocarbon rings and/or unsaturated hydrocarbon rings are condensed are preferably 2, 3, or 4 condensed saturated hydrocarbon rings and/or unsaturated hydrocarbon rings, and more preferably 2 or 3 condensed saturated hydrocarbon rings and/or unsaturated hydrocarbon rings. More specific examples include a decahydronaphthalene ring, an adamantane ring, a naphthalene ring, a phenanthrene ring, an anthracene ring, a pyrene ring, a triphenylene ring, a tetralin ring, 1,2,3,4,5,6,7,8-octahydronaphthalene ring, a norbornene ring, and the like.

In the present specification, a saturated hydrocarbon ring or an unsaturated hydrocarbon ring, or rings having a structure in which 2 to 6 saturated hydrocarbon rings and/or unsaturated hydrocarbon rings are condensed, are also collectively referred to as “hydrocarbon rings.”

The rings having a structure in which 2 saturated hydrocarbon rings and/or unsaturated hydrocarbon rings are connected are preferably rings represented by the formula (2):

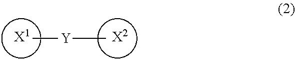

In the formula (2), X¹ ring and X² ring are the same or different, and each is a saturated hydrocarbon ring or an unsaturated hydrocarbon ring. That is, the X¹ ring and X² ring are both saturated hydrocarbon rings or unsaturated hydrocarbon rings; or one of them is a saturated hydrocarbon ring, and the other is an unsaturated hydrocarbon ring. It is preferable that the X¹ ring and the X² ring be both saturated hydrocarbon rings or unsaturated hydrocarbon rings. For example, it is preferable that the X¹ ring and the X² ring be both benzene rings or cyclohexane rings, or that one of them be a benzene ring and the other be a cyclohexane ring; and it is more preferable that both of them be benzene rings.

Moreover, Y is a bond, a C₁₋₆ alkylene group that may be substituted with a C₁₋₄ alkyl group, an oxygen atom (—O—), a sulfur atom (—S—), —SO—, or —SO₂—. Examples of the alkylene group include a methylene group, an ethylene group, a trimethylene group, a tetramethylene group, a hexamethylene group, and the like. Moreover, examples of the C₁₋₄ alkyl group as a substituent include a methyl group, an ethyl group, an n-propyl group, an isopropyl group, an n-butyl group, an isobutyl group, and the like. Preferable examples of the C₁₋₆ alkylene group substituted with a alkyl group include —CH(CH₃)—, —C(CH₃)₂—, —CH₂CH(CH₃)CH₂—, —CH₂C(CH₃)₂CH₂—, and the like. Y is preferably a bond, an oxygen atom, a methylene group, a dimethylmethylene group, —S—, or —SO₂—; and more preferably a bond, a dimethylmethylene group, an oxygen atom, or —SO₂—.

The rings represented by the formula (2) are substituted with R^{Xa}, R^{Xb}, R^{Xc}, and R^{Xd}. When the X ring of the formula (1) is rings represented by the formula (2), when three of R^{Xa} to R^{Xd} are hydrogen atoms, halogen atoms, or lower carbon substituents, and when the other one is a group of the formula (3), one of the X¹ ring and X² ring may be substituted with a group of the formula (3). In this case, the rings represented by the formula (2) are substituted with 0, 1, 2, or 3 halogen atoms or lower carbon substituents, and (number of halogen atoms or lower carbon substituents substituted in X¹ ring:number of halogen atoms or lower carbon substituents substituted in X² ring) can be (1:0), (0:1), (2:0), (1:1), (0:2), (3:0), (2:1), (1:2), or (0:3). When two of R^{Xa} to R^{Xd} are hydrogen atoms, halogen atoms, or lower carbon substituents, and when the other two are groups of the formula (3), one of the X¹ ring and X² ring may be substituted with 2 groups of the formula (3), or the X¹ ring and the X² ring each may be substituted with a group of the formula (3). It is preferable that the X¹ ring and the X² ring each be substituted with a group of the formula (3). In this case, the rings represented by the formula (2) are substituted with 0, 1, or 2 halogen atoms or lower carbon substituents, and (number of halogen atoms or lower carbon substituents substituted in X¹ ring:number of halogen atoms or lower carbon substituents substituted in X² ring) can be (1:0), (0:1), (2:0), (1:1), or (0:2). When one of R^{Xa} to R^{Xd} is a hydrogen atom, a halogen atom, or a lower carbon substituent, and when the other three are groups of the formula (3), one of the X¹ ring and X² ring may be substituted with 3 groups of the formula (3); the X¹ ring may be substituted with 2 groups of the formula (3), and the X² ring may be substituted with 1 group of the formula (3); or the X¹ ring may be substituted with 1 group of the formula (3), and the X² ring may be substituted with 2 groups of the formula (3). It is preferable that the X¹ ring be substituted with 2 groups of the formula (3), and the X² ring be substituted with 1 group of the formula (3); or that the X¹ ring be substituted with 1 group of the formula (3), and the X² ring be substituted with 2 groups of the formula (3). In this case, the rings represented by the formula (2) are substituted with 0 or 1 halogen atom or lower carbon substituent, and (number of halogen atoms or lower carbon substituents substituted in X¹ ring:number of halogen atoms or lower carbon substituents substituted in X² ring) may be (1:0) or (0:1). When all of R^{Xa} to R^{Xd} are groups of the formula (3), one of the X¹ ring and the X² ring may be substituted with 4 groups of the formula (3); the X¹ ring may be substituted with 3 groups of the formula (3), and the X² ring may be substituted with 1 group of the formula (3); the X¹ ring may be substituted with 1 group of the formula (3), and the X² ring may be substituted with 3 groups of the formula (3); or the X¹ ring may be substituted with 2 groups of the formula (3), and the X² ring may be substituted with 2 groups of the formula (3). It is preferable that the X¹ ring be substituted with 2 groups of the formula (3), and the X² ring be substituted with 2 groups of the formula (3).

As a group of the formula (1), a tetravalent group represented by the formula (1′):

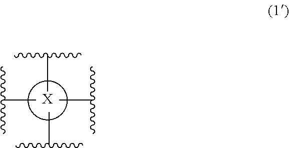

wherein in the formula (1′), X ring is as defined above;
is particularly preferably a group represented by the following formula. Specifically, the group is represented by the following formula:

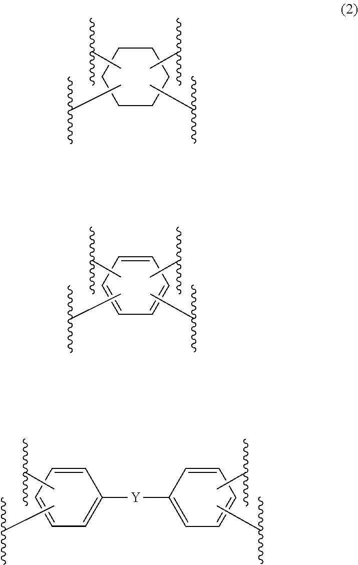

wherein in the formula (2^{g}), Y is as defined above.

In the formula (3), R¹ is the same or different, and is a C₁₋₁₈ alkyl group, a C₂₋₉ alkenyl group, a cycloalkyl group, an aryl group, or an aralkyl group, wherein one or more carbon atoms of these groups may be replaced by at least one atom selected from the group consisting of an oxygen atom and a nitrogen atom (preferably an oxygen atom). The one or more carbon atoms are preferably carbon atoms that are not directly bonded to the silicon atom. The one or more carbon atoms that may be replaced are one or plural (e.g., 2, 3, 4, 5, or 6) carbon atoms, and preferably one carbon atom. In terms of ease of synthesis etc., it is preferable that R¹ bonded to the same silicon atom be the same. It is more preferable that all R¹ present in the formula (1) be the same.

The C₁₋₁₈ alkyl group represented by R¹ is, for example, a linear or branched alkyl group. Examples include a methyl group, an ethyl group, an n-propyl group, an isopropyl group, an n-butyl group, an isobutyl group, a tert-butyl group, an n-pentyl group, a neopentyl group, a tert-pentyl group, an n-hexyl group, an n-heptyl group, a 2,2,4-trimethylpentyl group, an n-octyl group, an isooctyl group, an n-nonyl group, an n-decyl group, an n-dodecyl group, and the like. Preferable is a C₁₋₁₀ alkyl group, more preferable is a C₁₋₆ alkyl group, even more preferable is a C₁₋₃ alkyl group, and particularly preferable is a methyl group.

The C₂₋₉ alkenyl group represented by R¹ is, for example, a linear or branched alkenyl group. Examples include a vinyl group, an allyl group, a 2-propenyl group, a butenyl group, a pentenyl group, a hexenyl group, a heptenyl group, an octenyl group, a nonenyl group, and the like. Preferable is a C₂₋₄ alkenyl group.

The cycloalkyl group represented by R¹ is, for example, a 3- to 8-membered ring cycloalkyl group. Examples include a cyclopentyl group, a cyclohexyl group, a cycloheptyl group, a methylcyclohexyl group, and the like.

The aryl group represented by R¹ is, for example, a monocyclic or bicyclic aryl group. Examples include a phenyl group, a tolyl group, a xylyl group, an ethyl phenyl group, a naphthyl group, and the like. Of these, a phenyl group is preferable.

The aralkyl group represented by R¹ is, for example, a C₁₋₄ alkyl group substituted with an aryl group (particularly a phenyl group). Examples include a benzyl group, an α-phenethyl group, a β-phenethyl group, a β-methylphenethyl group, and the like.

R¹ is preferably a C₁₋₃ alkyl group, and more preferably a methyl group.

In the formula (3), R² is a C₁₋₁₈ (1, 2, 3, 4, 5, 6, 7, 8, 9, 10, 11, 12, 13, 14, 15, 16, 17, or 18) alkylene group. The alkylene group is a linear or branched alkylene group, and preferably a linear alkylene group. Examples include a methylene group, a methylmethylene group, an ethylmethylene group, a dimethylmethylene group, a diethylmethylene group, a dimethylene group (—CH₂CH₂—), a trimethylene group (—CH₂CH₂CH₂—), a tetramethylene group, a pentamethylene group, a hexamethylene group, a heptamethylene group, an octamethylene group, a nonamethylene group, a decamethylene group, an undecamethylene group, a dodecamethylene group, a tridecamethylene group, and the like. Specific examples include a C₂₋₁₈ alkylene group, preferably a C₂₋₁₀ alkylene group, more preferably a C₂₋₈ alkylene group, even more preferably a C₂₋₆ alkylene group, and particularly preferably a C₂₋₅ alkylene group.

One or more carbon atoms of the C₁₋₁₈ alkylene group may be replaced by at least one atom selected from the group consisting of an oxygen atom and a nitrogen atom (preferably an oxygen atom). The one or more carbon atoms are preferably carbon atoms that are not directly bonded to the silicon atom, and the 3- to 8-membered ring or epoxy ring. Moreover, the one or more carbon atoms that may be replaced are one or plural (e.g., 2, 3, 4, 5, or 6) carbon atoms, and preferably one carbon atom.

When the side of R² binding to the silicon atom is expressed as (*), examples of this group include (*)—C₂₋₉ alkylene-O—C₁₋₈ alkylene-, preferably (*)—C₂₋₄ alkylene-O—C₁₋₃ alkylene-, more preferably (*)—C₂₋₄ alkylene-O—C₁₋₂ alkylene-, and particularly preferably (*)—C₃ alkylene-O-methylene-.

Specific examples include (*)—(CH₂)₂—O—CH₂—, (*)—(CH₂)₃—O—CH₂—, (*)—(CH₂)₃—O—(CH₂)₂—, (*)—(CH₂)₅—O—(CH₂)₄—, and the like; of these, (*)—(CH₂)₃—O—CH₂ is preferable.

In the formula (3), m is an integer of 0 to 6 (i.e., 0, 1, 2, 3, 4, 5, or 6). Moreover, n is an integer of 0 to 3 (i.e., 0, 1, 2, or 3). The group bonded to R² of the formula (3) (on the side not binding to the silicon atom) is represented by the formula (4) (hereafter also referred to as “the group of the formula (4)”), as shown below.

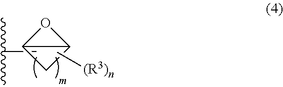

The group of the formula (4) wherein m is an integer of 1 to 6 is specifically described by the following structural formulas.

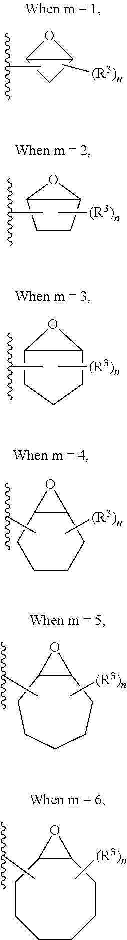

When m is 0, only an epoxy ring remains, and n is an integer of 0 to 3; thus, the group of the formula (4) is a group represented by any of the following formulas:

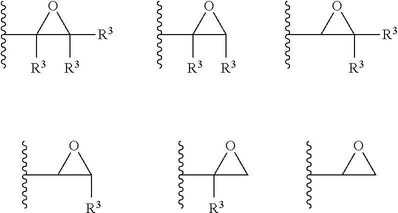

In the formula (3), R² and R³ bind to a 3- to 8-membered ring or an epoxy ring. n represents the number of R³ binding to the 3- to 8-membered ring or the epoxy ring.

In the formula (3), R³ is the same or different, and is a C₁₋₁₈ alkyl group, a C₂₋₉ alkenyl group, a cycloalkyl group, an aryl group, or an aralkyl group. One or more carbon atoms of these groups may be replaced by at least one atom selected from the group consisting of an oxygen atom and a nitrogen atom. The one or more carbon atoms are preferably carbon atoms that are not directly bonded to the 3- to 8-membered ring or epoxy ring. Moreover, the one or more carbon atoms that may be replaced are one or plural (e.g., 2, 3, 4, 5, or 6) carbon atoms, and preferably one carbon atom.

Examples of the C₁₋₁₈ alkyl group, C₂₋₉ alkenyl group, cycloalkyl group, aryl group, and aralkyl group represented by R³ include the same corresponding substituents represented by R¹ described above.

R³ is preferably a C₁₋₃ alkyl group, and more preferably a methyl group or an ethyl group.

Preferable examples of the group of the formula (3) include groups wherein R¹, R², R³, m, and n are as defined above; all R¹ are the same; and all R³ are the same (when there are plural R³). The number of this group present in the epoxy resin represented by the formula (1) is 1, 2, 3, or 4; and they may be the same or different, and are preferably the same.

Particularly preferable specific examples of the group of the formula (4) include groups wherein R³ is as defined above; m is 0, 1, 2, 3, or 4; and n is 0, 1, or 2. More preferable among these are, for example, the following groups (all R³ are as defined above):

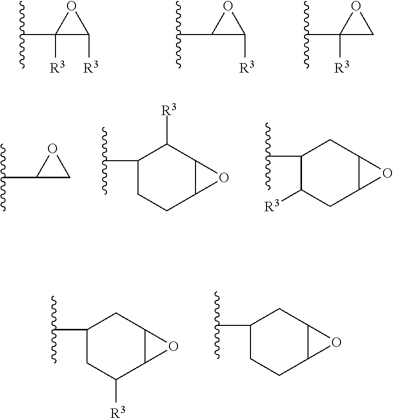

The number of groups of the formula (4) present in the epoxy resin represented by the formula (1) is 1, 2, 3, or 4; and they may be the same or different, and are preferably the same.

Moreover, one or more hydrogen atoms bonded to one or more carbon atoms that constitute the hydrocarbon ring constituting the X ring, and that are not bonded to R^{Xa}, R^{Xb}, R^{Xc}, or R^{Xd}, may be replaced by a lower carbon substituent or a halogen atom (preferably a lower carbon substituent). That is, when the X ring is a saturated hydrocarbon ring or an unsaturated hydrocarbon ring, or rings having a structure in which 2 to 6 saturated hydrocarbon rings and/or unsaturated hydrocarbon rings are condensed, one or more hydrogen atoms bonded to one or more carbon atoms that constitute these rings, and that are not bonded to R^{Xa}, R^{Xb}, R^{Xc}, or R^{Xd}, may be replaced by a lower carbon substituent or a halogen atom (preferably a lower carbon substituent). When the X ring is rings having a structure in which 2 saturated hydrocarbon rings and/or unsaturated hydrocarbon rings are connected, one or more hydrogen atoms bonded to one or more carbon atoms that constitute theses connected saturated hydrocarbon rings and/or unsaturated hydrocarbon rings, and that are not bonded to R^{Xa}, R^{Xb}, R^{Xc}, or R^{Xd} may be replaced by a lower carbon substituent or a halogen atom (preferably a lower carbon substituent). When the case in which the X ring is rings represented by the formula (2) is explained in detail, one or more hydrogen atoms bonded to one or more carbon atoms that constitute the X¹ ring and X² ring, and that are not bonded to R^{Xa}, R^{Xb}, R^{Xc}, or R^{Xd}, may be replaced by a lower carbon substituent or a halogen atom (preferably a lower carbon substituent).

In the present specification, carbon atoms that constitute the hydrocarbon ring constituting the X ring, and that are not bonded to R^{Xa}, R^{Xb}, R^{Xc}, and R^{Xd}, are also referred to as “R^{Xa-d} non-binding carbon atoms.”

The lower carbon substituent or halogen atom that may replace one or more hydrogen atoms bonded to one or more R^{Xa-d} non-binding carbon atoms is preferably singly bonded to one R^{Xa-d} non-binding carbon atom. That is, when hydrogen atoms bonded to R^{Xa-d} non-binding carbon atoms are replaced, only one of the hydrogen atoms bonded to the R^{Xa-d} non-binding carbon atoms is preferably replaced by a lower carbon substituent or halogen atom. Moreover, the number of substituents (i.e., the total number of lower carbon substituents and halogen atoms) is more preferably less than the number of R^{Xa-d} non-binding carbon atoms. More specifically, the number of substituents is preferably 1 to 6 (1, 2, 3, 4, 5, or 6), more preferably 1 to 4, and even more preferably 1 or 2. Particularly when the X ring is rings represented by the formula (2), one or more hydrogen atoms to be replaced are preferably hydrogen atoms bonded to carbon atoms that are not bonded to Y.

When at least one of R^{Xa}, R^{Xb}, R^{Xc}, and R^{Xd} is a lower carbon substituent, and when at least one lower carbon substituent is bonded to an R^{Xa-d} non-binding carbon atom, all of the lower carbon substituents are preferably the same. That is, when there are lower carbon substituents among R^{Xa}, R^{Xb}, R^{Xc}, and R^{Xd}, and when there are lower carbon substituents bonded to R^{Xa-d} non-binding carbon atoms, all of the lower carbon substituents are preferably the same. Moreover, when at least one of R^{Xa}, R^{Xb}, R^{Xc}, and R^{Xd} is a halogen atom, and when at least one halogen atom is bonded to an R^{Xa-d} non-binding carbon atom, all of the halogen atoms are preferably the same. That is, when there are halogen atoms among R^{Xa}, R^{Xb}, R^{Xc}, and R^{Xd}, and when there are halogen atoms bonded to R^{Xa-d} non-binding carbon atoms, all of the halogen atoms are preferably the same.

More specifically, for example, when the tetravalent group represented by the above formula (1′) is the following:

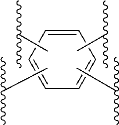

preferable examples of the epoxy resin represented by the formula (1) include an epoxy resin represented by the formula (1-X1):

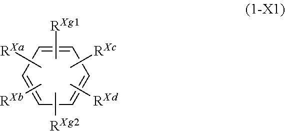

wherein in the formula (1-X1), R^{Xa}. R^{Xb}, R^{Xc} and R^{Xd} are as defined above; and R^{Xg1} and R^{Xg2} are the same or different, and each is a hydrogen atom, a lower alkyl group, a lower alkoxy group, or a lower alkenyl group.
In the formula (1-X1), R^{Xa}, R^{Xb}, R^{Xc}, R^{Xa}, R^{Xg1} and R^{Xg2} are more preferably each bonded to a different carbon atom on the benzene ring. Among the epoxy resins represented by the formula (1-X1), one wherein R^{Xg1} and R^{Xg2} are hydrogen atoms is preferable.

More preferable examples of the epoxy resin represented by the formula (1-X1) include:

an epoxy resin represented by the formula (1-X1a):

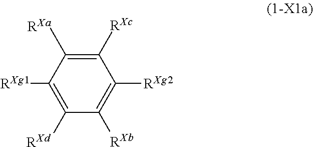

wherein in the formula (1-X1a), R^{Xa}, R^{Xb}, R^{Xc}, and R^{Xd} are as defined above; and R^{Xg1} and R^{Xg2} are as defined above; and

an epoxy resin represented by the formula (1-X1b):

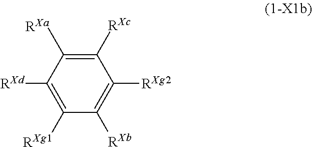

wherein in the formula (1-X1b), R^{Xa}, R^{Xb}, R^{Xc}, and R^{Xd} are as defined above; and R^{Xg1} and R^{Xg2} are as defined above.

More preferable among the epoxy resins represented by the formula (1-X1a) are, for example, those wherein R^{Xa} and R^{Xb} are hydrogen atoms, R^{Xc} and R^{Xd} are groups of the formula (3), and R^{Xg1} and R^{Xg2} are hydrogen atoms; and those wherein R^{Xa} and R^{Xc} are hydrogen atoms, R^{Xb} and R^{Xd} are groups of the formula (3), and R^{Xg1} and R^{Xg2} are hydrogen atoms.

More preferable among the epoxy resins represented by the formula (1-X1b) are, for example, those wherein R^{Xa} is a hydrogen atom, R^{Xb}, R^{Xc}, and R^{Xd} are groups of the formula (3), and R^{Xg1} and R^{Xg2} are hydrogen atoms.

Moreover, when the tetravalent group represented by the above formula (1′) is a group represented by the following formula:

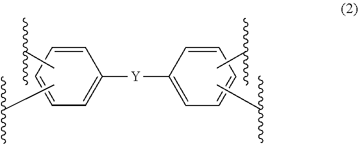

wherein in the formula (2^{g}), Y is as defined above;
preferable examples of the epoxy resin represented by the formula (1) also include an epoxy resin represented by the formula (1-X2):

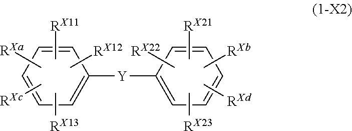

wherein in the formula (1-X2), Y is as defined above; R^{Xa}, R^{Xb}, R^{Xc}, and R^{Xd} are as defined above; and R^{X11}, R^{X12}, and R^{X13}, as well as R^{X21}, R^{X22}, and R^{X23} are the same or different, and each is a hydrogen atom, a lower alkyl group, a lower alkoxy group, or a lower alkenyl group.
In the formula (1-X2), R^{Xa}, R^{Xc}, R^{X11}, R^{X12}, and R^{X13} preferably each bind to a different carbon atom; and R^{Xb}, R^{Xd}, R^{X21}, R^{X22}, and R^{X23} more preferably each bind to a different carbon atom. None of R^{Xa}, R^{Xb}, R^{Xc}, R^{Xd}, R^{X11}, R^{X12}, R^{X13}, R^{X21}, R^{X22}, and R^{X23} binds to a carbon atom bonded to Y.

More preferable among the epoxy resins represented by the formula (1-X2) are:

an epoxy resin represented by the formula (1-X2a):

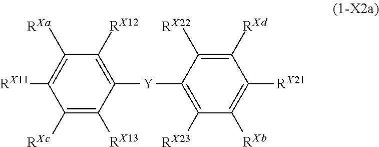

wherein in the formula (1-X2a), Y is as defined above; R^{Xa}, R^{Xb}, R^{Xc}, and R^{Xd} are as defined above; and R^{X11}, R^{X12}, and R^{X13}, as well as R^{X21}, R^{X22}, and R^{X23} are the same or different, and each is a hydrogen atom, a lower alkyl group, a lower alkoxy group, or a lower alkenyl group;

an epoxy resin represented by the formula (1-X2b):

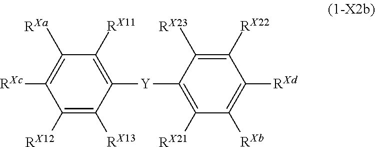

wherein in the formula (1-X2b), Y is as defined above; R^{Xa}, R^{Xb}, R^{Xc}, and R^{Xd} are as defined above; and R^{X11}, R^{X12} and R^{X13}, as well as R^{X21}, R^{X22}, and R^{X23} are the same or different, and each is a hydrogen atom, a lower alkyl group, a lower alkoxy group, or a lower alkenyl group; and

an epoxy resin represented by the formula (1-X2c):

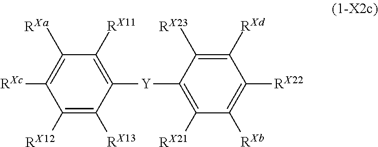

wherein in the formula (1-X2c), Y is as defined above; R^{Xa}, R^{Xb}, R^{Xc}, and R^{Xd} are as defined above; and R^{X11}, R^{X12} and R^{X13}, as well as R^{X21}, R^{X22}, and R^{X23} are the same or different, and each is a hydrogen atom, a lower alkyl group, a lower alkoxy group, or a lower alkenyl group.

More preferable among the epoxy resins represented by the formula (1-X2a) are, for example, those wherein R^{Xa}, R^{Xb}, R^{Xc}, and R^{Xd} are groups of the formula (3); R^{X11} and R^{X21} are lower carbon substituents; and R^{X12}, R^{X13}, R^{X22}, and R^{X23} are hydrogen atoms. Particularly preferable are those wherein Y is a C₁₋₆ alkylene group that may be substituted with a C₁₋₄ alkyl group (particularly —C(CH₃)₂—); R^{Xa}, R^{Xb}, R^{Xc} and R^{Xd} are groups of the formula (3); R^{X11} and R^{X21} are lower alkoxy groups; and R^{X12}, R^{X13}, R^{X22}, and R^{X23} are hydrogen atoms. In these cases, it is more preferable that all of the groups of the formula (3) as R^{Xa}, R^{Xb}, R^{Xc}, and R^{Xd} be the same, and that the lower carbon substituents as R^{X11} and R^{X21} be the same.

Preferable among the epoxy resins represented by the formula (1-X2b) are, for example, those wherein R^{Xa} and R^{Xb} are hydrogen atoms; R^{Xc} and R^{Xd} are groups of the formula (3); and R^{X11}, R^{X12}, R^{X13}, R^{X21}, R^{X22}, and R^{X23} are hydrogen atoms. In this case, it is more preferable that the groups of the formula (3) as R^{Xc} and R^{Xd} be the same.

Preferable among the epoxy resins represented by the formula (1-X2c) are, for example, those wherein R^{Xa} is a hydrogen atom; R^{Xb}, R^{Xc}, and R^{Xd} are groups of the formula (3); and R^{X11}, R^{X12}, R^{X13}, R^{X21}, R^{X22}, and R^{X23} are hydrogen atoms. In this case, it is more preferable that the groups of the formula (3) as R^{Xb}, R^{Xc}, and R^{Xd} be the same.

In the present specification, the explanations relating to the X ring, R^{Xa}, R^{Xb}, R^{Xc}, and R^{Xd} in the formula (1), and R¹, R², R³, m, and n in the group of the formula (3), including the explanation about the group of the formula (4), can be combined in any way. Any epoxy resins represented by combinations thereof can be also used in the present invention.

The formula (1) can satisfy any of the following:

(iia) one or more hydrogen atoms bonded to one or more R^{Xa-d} non-binding carbon atoms are not replaced; R^{Xa} and R^{Xb} of R^{Xa}, R^{Xb}, R^{Xc}, and R^{Xd} are hydrogen atoms; and R^{Xc} and R^{Xd} are groups of the formula (3);
(iiia) one or more hydrogen atoms bonded to one or more R^{Xa-d} non-binding carbon atoms are not replaced; R^{Xa} of R^{Xa}, R^{Xb}, R^{Xc}, and R^{Xd} is a hydrogen atom; and R^{Xb}, R^{Xc}, and R^{Xd} are groups of the formula (3); or
(iva) one or more hydrogen atoms bonded to one or more R^{Xa-d} non-binding carbon atoms are not replaced; and all of R^{Xa}, R^{Xb}, R^{Xc}, and R^{Xd} are groups of the formula (3).

In the case of (iia), preferable examples of the epoxy resin represented by the formula (1) include an epoxy resin represented by the following formula (1-iia):

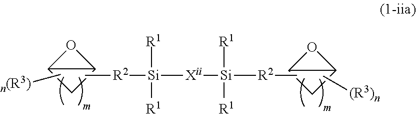

wherein Xⁱⁱ is a divalent group obtained by removing two hydrogen atoms from a hydrocarbon ring, or a divalent group represented by the formula (2^{g}-iia):

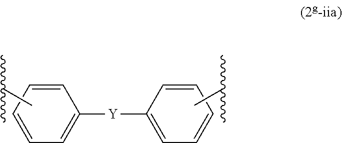

wherein Y is as defined above; and
R¹, R², R³, m, and n are as defined above.
R¹, R², R³, m, and n each may be the same or different, and are preferably the same.

The divalent group represented by Xⁱⁱ is preferably a cyclohexane-1,4-diyl group or a 1,4-phenylene group; and more preferably a 1,4-phenylene group.

Preferable among the divalent groups represented by the formula (2^{g}-iia) is a group represented by the formula (2^{g}-iia′):

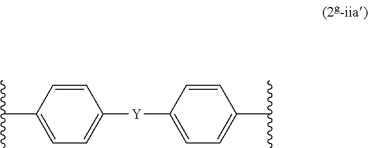

wherein Y is as defined above.

In the formula (2^{g}-iia′), Y is preferably a bond, a dimethylmethylene group, an oxygen atom, or —SO₂—.

Xⁱⁱ is preferably a cyclohexane-1,4-diyl group, a 1,4-phenylene group, or a group of the formula (2^{g}-iia′); and more preferably a 1,4-phenylene group.

The present invention can more preferably use, for example, an epoxy resin represented by the formula (1-iia), wherein m is the same and is 0, 1, 2, 3, or 4 (particularly preferably m is the same and is 0 or 4); n is the same and is 0 (that is, the ring is not substituted with R³) Xⁱⁱ is a divalent group obtained by removing two hydrogen atoms from a hydrocarbon ring (particularly preferably a benzene ring); R¹ is the same and is a C₁₋₃ alkyl group; and R² is the same and is a C₂₋₆ alkylene group, wherein one carbon atom that is not directly bonded to the silicon atom, and the 3- to 6-membered ring or epoxy ring may be replaced by an oxygen atom.

In the case of (iiia), the epoxy resins represented by the formula (1) preferably include an epoxy resin represented by the following formula (1-iiia):

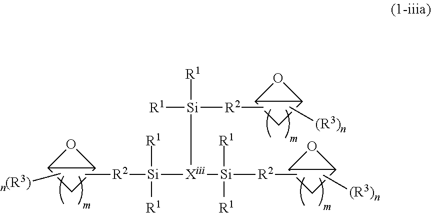

wherein Xⁱⁱⁱ is a trivalent group obtained by removing three hydrogen atoms from a hydrocarbon ring, or a trivalent group represented by the formula (2^{g}-iiia):

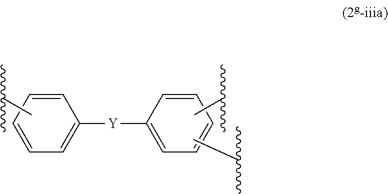

wherein Y is as defined above; and
R¹, R², R³, m, and n are as defined above.
R¹, R², R³, m, and n each may be the same or different, and are preferably the same.

Preferable examples of the trivalent group represented by Xⁱⁱⁱ include the following groups:

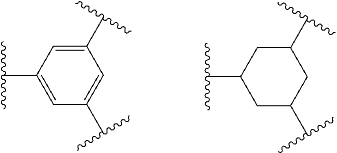 [SMILES: *c1cc(*)cc(*)c1 ; *C1CC(*)CC(*)C1]

Preferable among the trivalent groups represented by the formula (2^{g}-iiia) include a group represented by the formula (2^{g}-iiia′):

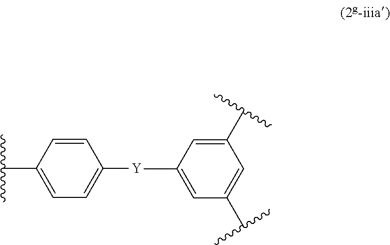

wherein Y is as defined above.

In the formula (2^{g}-iiia′), Y is particularly preferably a bond, a dimethylmethylene group, an oxygen atom, or —SO₂—.

The present invention can more preferably use, for example, an epoxy resin represented by the formula (1-iiia), wherein m is the same and is 0, 1, 2, 3, or 4 (particularly preferably m is the same and is 0 or 4); n is the same and is 0 (that is, the ring is not substituted with R³); Xⁱⁱⁱ is a trivalent group obtained by removing three hydrogen atoms from a hydrocarbon ring (particularly preferably a benzene ring); R¹ is the same and is a C₁₋₃ alkyl group; and R² is the same and is a C₂₋₆ alkylene group, wherein one carbon atom that is not directly bonded to the silicon atom and the 3- to 6-membered ring or epoxy ring may be replaced by an oxygen atom.

In the case of (iva), the epoxy resins represented by the formula (1) include an epoxy resin represented by the following formula (1-iva):

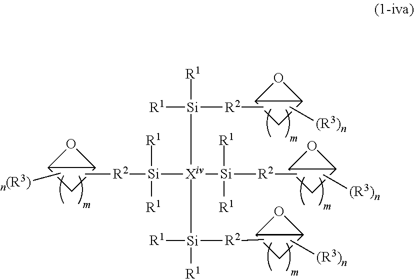

wherein X^{iv} is a tetravalent group represented by the above formula (1′), wherein one or more hydrogen atoms bonded to one or more R^{Xa-d} non-binding carbon atoms in the X ring are not replaced; and R¹, R², R³, m, and n are as defined above. R¹, R², R³, m, and n each may be the same or different, and are preferably the same.

Preferable examples of the tetravalent group represented by X^{iv} include the following groups:

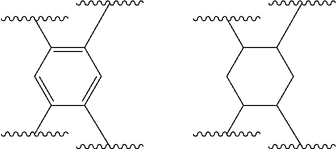 [SMILES: *c1cc(*)c(*)cc1* ; *C1CC(*)C(*)CC1*]

As the tetravalent group represented by X^{iv}, among tetravalent groups represented by the formula (2^{g}), wherein one or more hydrogen atoms bonded to one or more R^{Xa-d} non-binding carbon atoms are not replaced, preferable is a group represented by the formula (2^{g}-iva′):

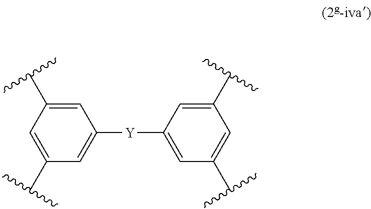

wherein Y is as defined above.

In the formula (2^{g}-iva′), Y is particularly preferably a bond, a dimethylmethylene group, an oxygen atom, or —SO₂—.

The present invention can more preferably use, for example, an epoxy resin represented by the formula (1-iva), wherein m is the same and is 0, 1, 2, 3, or 4 (particularly preferably m is the same and is 0 or 4); n is the same and is 0 (that is, the ring is not substituted with R³); X^{iv} is a tetravalent group obtained by removing four hydrogen atoms from a hydrocarbon ring (particularly preferably a benzene ring); R¹ is the same and is a C₁₋₃ alkyl group; and R² is the same and is a C₂₋₆ alkylene group, wherein one carbon atom that is not directly bonded to the silicon atom and the 3- to 6-membered ring or epoxy ring may be replaced by an oxygen atom.

More preferable among the epoxy resins represented by the formula (1) are specifically, for example, compounds represented by the formula (1-IIa):

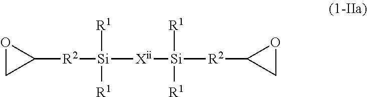

wherein R¹, R², and Xⁱⁱ are as defined above.

Preferable among the compounds represented by the formula (1-IIa) are compounds wherein Xⁱⁱ is a 1,4-phenylene group or a group represented by the formula (2^{g}-iia′) (preferably a 1,4-phenylene group); R¹ is the same or different (preferably the same), and is a C₁₋₃ alkyl group (particularly a methyl group); and R² is the same or different (preferably the same), and is a C₂₋₆ alkylene group, (*)—(CH₂)₂—O—CH₂—, (*)—(CH₂)₃—O—CH₂—, (*)—(CH₂)₃—O—(CH₂)₂—, or (*)—(CH₂)₅—O—(CH₂)₄—. (*) represents the side of R² binding to the silicon atom, as described above.

More preferable among the epoxy resins represented by the above formula (1-IIa) is:

an epoxy resin represented by the formula (1-IIa1):

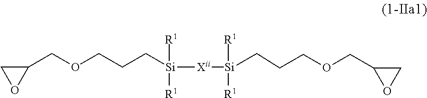

wherein R¹ and Xⁱⁱ are as defined above; or

an epoxy resin represented by the formula (1-IIa2):

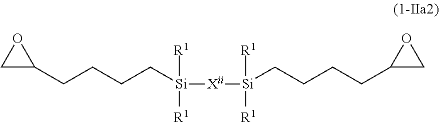

wherein R¹ and Xⁱⁱ are as defined above.
R¹ may be the same or different, and is preferably the same.

More preferably, in the formula (1-IIa1) or (1-IIa2), R¹ is the same or different (preferably the same), and is a C₁₋₃ alkyl group (particularly a methyl group); and Xⁱⁱ is a 1,4-phenylene group or a group represented by the formula (2^{g}-iia′).

More preferable among the epoxy resins represented by the formula (1) include an epoxy resin represented by the formula (1-IIb):

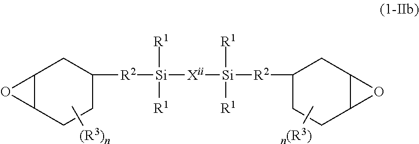

wherein R¹, R², R³, Xⁱⁱ, and n are as defined above.
R¹, R², R³, and n each may be the same or different, and are preferably the same.

More preferably, in the formula (1-IIb), Xⁱⁱ is a 1,4-phenylene group or a group represented by the formula (2^{g}-iia′) (preferably a 1,4-phenylene group); R¹ is the same or different (preferably the same), and is a C₁₋₃ alkyl group (particularly a methyl group); both n is 0 (that is, the ring is not substituted with R³); and R² is the same or different (preferably the same), and is a C₂₋₆ alkylene group (preferably a dimethylene group: —(CH₂)₂—).

More preferable among the epoxy resins represented by the formula (1) is an epoxy resin represented by the formula (1-IIIa):

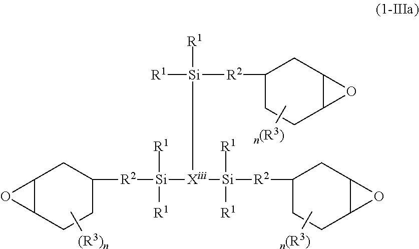

wherein R¹, R², R³, Xⁱⁱⁱ, and n are as defined above.
R¹, R², R³, and n each may be the same or different, and are preferably the same.

More preferably, in the formula (1-IIIa), Xⁱⁱⁱ is

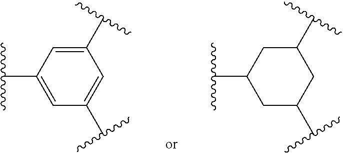 [SMILES: *c1cc(*)cc(*)c1 ; *C1CC(*)CC(*)C1]

or a group represented by the formula (2^{g}-iiia′); R¹ is the same or different (preferably the same), and is a C₁₋₃ alkyl group (particularly a methyl group); both n is 0 (that is, the ring is not substituted with R³); and R² is the same or different (preferably the same), and is a C₂₋₆ alkylene group (preferably a dimethylene group: —(CH₂)₂—).

In the epoxy resin composition of the present invention, the epoxy resins represented by the formula (1) can be used singly or in combination of two or more.

The epoxy resin represented by the formula (1) can be produced by or according to a known method, for example, based on or according to the disclosure of the patent literature (GB1123960B). Moreover, the epoxy resin represented by the formula (1-iia) can be produced by, for example, a reaction represented by the following reaction formula:

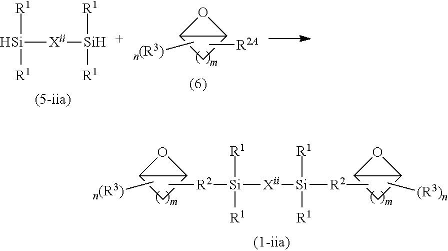

wherein R^{2A} is a C₂₋₁₈ alkenyl group, wherein one or more carbon atoms of this group may be replaced by at least one atom selected from the group consisting of an oxygen atom and a nitrogen atom; and R¹, R², R³, and Xⁱⁱ are as defined above.

The C₂₋₁₈ alkenyl group represented by R^{2A} is a linear or branched alkenyl group, and preferably a linear alkenyl group. Specific examples include a vinyl group, an allyl group, a propenyl group, a butenyl group, a pentenyl group, a hexenyl group, a heptenyl group, an octenyl group, a norbornenyl group, a cyclohexenyl group, and the like. A C₂₋₁₀ alkenyl group is preferable; a C₂₋₈ alkenyl group is more preferable; a C₂₋₆ alkenyl group is even more preferable; and a vinyl group, an allyl group, or a butenyl group is particularly preferable. The alkenyl group is preferably an α-alkenyl group.

One or more carbon atoms of these C₂₋₁₈ alkenyl groups may be replaced by at least one atom selected from the group consisting of an oxygen atom and a nitrogen atom (preferably an oxygen atom). The one or more carbon atoms are preferably carbon atoms that are not directly bonded to the epoxy ring. Moreover, the one or more carbon atoms that may be replaced are one or plural (e.g., 2, 3, 4, 5, or 6) carbon atoms, and preferably one carbon atom. Examples of this group include C₂₋₉ alkenyl-O—C₁₋₈ alkylene-, preferably C₂₋₄ alkenyl-O—C₁₋₃ alkylene-, more preferably C₂₋₄ alkenyl-O—C₁₋₂ alkylene-, and particularly preferably C₃ alkenyl-O—CH₂—. Specific examples include CH₂═CH—O—CH₂—, CH₂═CH—CH₂—O—CH₂—, CH₂═CH—CH₂—O—(CH₂)₂—, CH₂═CH—(CH₂)₃—O—(CH₂)₄—, and the like; among these, CH₂═CH—CH₂—O—CH₂-(allyloxymethyl group) is preferable.

The epoxy resin represented by the formula (1-iia) can be produced by hydrosilylation of the compound represented by the formula (5-iia) and the compound represented by the formula (6). Hydrosilylation can be generally performed in the presence of a catalyst in the presence or absence of a solvent. Moreover, when a compound represented by the formula (5-iiia):

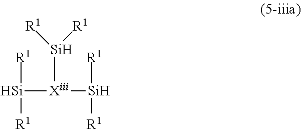

wherein R¹ and Xⁱⁱⁱ are as defined above; or
the formula (5-iva):

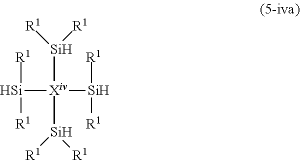

wherein R¹ and X^{iv} are as defined above; or
the formula (5-ia):

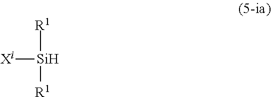

wherein Xⁱ is a monovalent group obtained by removing one hydrogen atom from a hydrocarbon ring, and R¹ is as defined above; is used in place of the compound represented by the formula (5-iia), an epoxy resin represented by the above formula (1-iiia) or (1-iva), or an epoxy resin having a structure in which one group of the formula (3) is bonded to a hydrocarbon ring can also be produced. Moreover, various compounds represented by the formula (1) can be produced by using compounds having a structure in which Xⁱ to X^{iv} are each replaced by a monovalent group obtained by removing one hydrogen atom from the X ring, a divalent group obtained by removing two hydrogen atoms from the X ring, a trivalent group obtained by removing three hydrogen atoms from the X ring, or a tetravalent group obtained by removing four hydrogen atoms from the X ring.

The catalyst used in hydrosilylation may be a known catalyst. Examples include platinum-based catalysts, such as platinum carbon, chloroplatinic acid, olefin complexes of platinum, alkenylsiloxane complexes of platinum, and carbonyl complexes of platinum; rhodium-based catalysts, such as tris(triphenylphosphine)rhodium; and iridium-based catalysts, such as bis(cyclooctadienyl)dichloroiridium. These catalysts may be in the form of solvates (e.g., hydrates, alcoholates, etc.). Further, the catalyst may be used in the form of a solution obtained by dissolving the catalyst in an alcohol (e.g., ethanol) when used. These catalysts can be used singly or in combination of two or more.

The amount of the catalyst used may be an effective amount as the catalyst. For example, the amount of the catalyst used is generally 0.00001 to 20 parts by mass, and preferably 0.0005 to 5 parts by mass, based on the total amount of 100 parts by mass of the compound represented the formula (5-ia), (5-iia), (5-iiia), or (5-iva), and the compound represented by the formula (6).

Although hydrosilylation proceeds without use of a solvent, the reaction can be carried out under milder conditions by using a solvent. Examples of solvents include aromatic hydrocarbon solvents, such as toluene and xylene; aliphatic hydrocarbon solvents, such as hexane and octane; ether solvents, such as tetrahydrofuran and dioxane; alcohol solvents, such as ethanol and isopropanol; and the like. These may be used singly or in combination of two or more.

The amount of the compound represented by the formula (6) is, for example, generally 0.5 to 2 mol, preferably 0.6 to 1.5 mol, and more preferably 0.8 to 1.2 mol, per mol of the Si—H group in the compound represented by the formula (5-ia), (5-iia), (5-iiia), or (5-iva).

The reaction temperature is generally 0° C. to 150° C., and preferably 10° C. to 120° C. The reaction time is generally about 1 hour to 24 hours.

After completion of the reaction, the solvent is distilled off from the reaction mixture, or a known isolation method is used, thereby obtaining an epoxy resin represented by the formula (1).

The specific phenol-based curing agent used in the present invention is a phenol resin that is liquid at 25° C. at one atmosphere. In the present specification, unless otherwise specified, being liquid at 25° C. refers to being liquid at 25° C. at one atmosphere. Further, unless otherwise specified, the liquid phenol resin refers to a phenol resin that is liquid at 25° C. at one atmosphere.

The phenol-based curing agent may be configured from a single resin or two or more resins, as long as it is liquid at 25° C. as a whole. The viscosity of the liquid phenol-based curing agent at 25° C. is, for example, 0.1 to 3000 Pa·s. Moreover, in terms of the better handling properties of the epoxy resin composition after mixing, the viscosity is preferably 0.1 to 500 Pa·s, and more preferably 0.1 to 100 Pa·s. The viscosity is a value measured using a B-type viscometer at 25° C. at a rotational speed of 20 rpm.

The molecular weight of the liquid phenol resin is preferably 100 to 3000, and more preferably 100 to 1000, in terms of even better handling properties.

Examples of liquid phenol-based curing agents that can be suitably used for the epoxy resin composition of the present invention include liquid allylphenol resins, liquid propenylphenol resins, and liquid alkylphenol resins.

More specifically, it is possible to use, for example, a phenol resin represented by the formula (7):

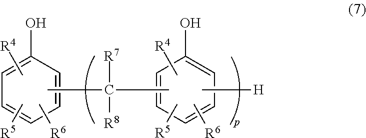

wherein R⁴ to R⁶ are the same or different, and each is a hydrogen atom, a C₂₋₉ alkenyl group, a C₁₋₁₈ alkyl group, or a C₁₋₉ alkylol group; R⁷ and R⁸ are the same or different, and each is a hydrogen atom or a C₁₋₄ alkyl group; and p is an average value of 0 to 6; provided that not all of R⁴ are hydrogen atoms, not all of R⁵ are hydrogen atoms, and not all of R⁶ are hydrogen atoms.

It is highly likely that phenol resins having a structure in which at least some of the phenols are replaced by a C₂₋₉ alkenyl group, a C₁₋₁₈ alkyl group, or a C₁₋₉ alkylol group are phenol resins that are liquid at 25° C. In particular, it is extremely highly likely that phenol resins having a structure in which at least 30% or more, 40% or more, or 50% or more of the phenols in the repeating phenol units are replaced are phenol resins that are liquid at 25° C.

In the present specification, the C₂₋₉ (2, 3, 4, 5, 6, 7, 8, or 9) alkenyl group is a linear or branched alkenyl group. Examples include a vinyl group, an allyl group, a 1-propenyl group, a butenyl group, a pentenyl group, a hexenyl group, a heptenyl group, an octenyl group, a nonenyl group, and the like. A C₂₋₄ alkenyl group is preferable, and an allyl group is particularly preferable.

In the present specification, the C₁₋₁₈ (1, 2, 3, 4, 5, 6, 7, 8, 9, 10, 11, 12, 13, 14, 15, 16, 17, or 18) alkyl group is a linear or branched alkyl group. Examples include a methyl group, an ethyl group, an n-propyl group, an isopropyl group, an n-butyl group, an isobutyl group, a tert-butyl group, an n-pentyl group, a neopentyl group, a tert-pentyl group, an n-hexyl group, an n-heptyl group, a 2,2,4-trimethylpentyl group, an n-octyl group, an isooctyl group, an n-nonyl group, an n-decyl group, an n-dodecyl group, and the like. Preferable are C₁₋₁₀ alkyl groups, more preferable are C₁₋₆ alkyl groups, and even more preferable are C₁₋₄ alkyl groups.

In the present specification, the C₁₋₉ (1, 2, 3, 4, 5, 6, 7, 8, or 9) alkylol group is linear or branched alkylol group. Examples include a methylol group, an ethylol group, a propyrrole group, a butyrol group, a pentylol group, a hexylol group, a heptyrol group, an octylol group, a nonylol group, and the like. Preferable are C₁₋₆ alkylol groups, more preferable are C₁₋₃ alkylol groups, and particularly preferable is a methylol group.

In the present specification, the C₁₋₄ (1, 2, 3, or 4) alkyl group is a linear or branched alkyl group. Examples include a methyl group, an ethyl group, an n-propyl group, an isopropyl group, an n-butyl group, an isobutyl group, a tert-butyl group, and the like.

In the formula, R⁷ and R⁸ are particularly preferably hydrogen atoms.

p is an average value of 0 to 6. p is preferably larger than 0. The upper or lower limit of the above range of p may be, for example, 1, 2, 3, 4, or 5. For example, p is more preferably an average value of 1 to 4.

The liquid phenol resin is preferably, of the phenol resins represented by the formula (7), one wherein R⁴ is R⁴⁻¹ or R⁴⁻²; R⁴⁻¹ is the same or different, and is a C₂₋₉ alkenyl group, a C₁₋₁₈ alkyl group, or a C₁₋₉ alkylol group; and R⁴⁻² is the same, and is a hydrogen atom, a C₂₋₉ alkenyl group, a C₁₋₁₈ alkyl group, or a C₁₋₉ alkylol group; provided that R⁴⁻¹ and R⁴⁻² are not the same, and the phenol unit having R⁴⁻¹ and the phenol unit having R⁴⁻² are randomly (preferably alternately) linked.

Of the phenol resins represented by the formula (7), preferable is, for example, a phenol resin represented by the formula (7a):

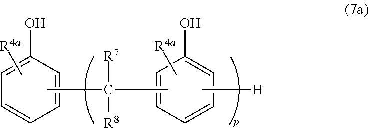

wherein R^{4a} is the same or different, and is a C₂₋₉ alkenyl group, a C₁₋₁₈ alkyl group, or a C₁₋₉ alkylol group; and R⁷, R⁸, and p are as defined above. Particularly preferable is a phenol resin represented by the formula (7a′):

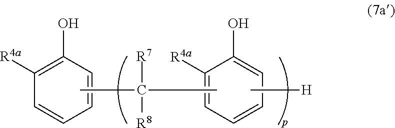

wherein R^{4a}, R⁷, R⁸, and p are as defined above.

Further, for example, a preferable phenol resin is represented by the formula (7b):

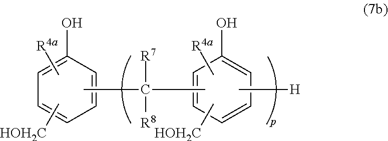

wherein R^{4a}, R⁷, R⁸ and p are as defined above.

Preferable among the phenol resins represented by the formula (7a), (7a′), or (7b) are those wherein R^{4a} is R^{4a1} or R^{4a2}, R^{4a1} is the same, R^{4a2} is the same, and the phenol unit having R^{4a1} and the phenol unit having R^{4a2} are randomly (preferably alternately) linked. In this case, R^{4a1} and R^{4a2} are each a C₂₋₉ alkenyl group, a C₁₋₁₈ alkyl group, or a alkylol group, as with R^{4a}. However, R^{4a1} and R^{4a2} are not the same.

The mixing ratio of the liquid phenol-based curing agent in the epoxy resin composition of the present invention may be within the range in which the effects of the present invention can be exhibited. For example, the ratio of the equivalent of reactive functional groups (hydroxyl groups) in the liquid phenol-based curing agent to the equivalent of epoxy groups in the epoxy resin is preferably 10:90 to 90:10, more preferably 20:80 to 80:20, even more preferably 30:70 to 70:30, and still more preferably 40:60 to 60:40.

Although it depends on the proportion of the equivalent of reactive functional groups as described above, the amount of the liquid phenol-based curing agent is, for example, preferably 10 to 150 parts by mass, more preferably 20 to 100 parts by mass, and even more preferably 30 to 80 parts by mass, based on 100 parts by mass of the epoxy resin in the epoxy resin composition. The lower limit may be, for example, 40 or 50 parts by mass.

In the epoxy resin composition of the present invention, a curing accelerator may be used in combination, when the above curing agent is used. Examples include imidazoles, such as 2-methylimidazole, 2-ethylimidazole, 2-phenylimidazole, 2-ethyl-4-methylimidazole, 1,2-dimethylimidazole, 1-(2-cyanoethyl)-2-ethyl-4-methylimidazole, 2-undecylimidazole, and 2-phenylimidazoline; tertiary amines, such as 2-(dimethylaminomethyl) phenol, triethylenediamine, triethanolamine, 1,8-diazabicyclo(5,4,0)undecene-7, and 1,5-diazabicyclo(4,3,0)-nonen-5; organic phosphines, such as triphenylphosphine, diphenylphosphine, and tributylphosphine; metal compounds, such as tin octylate; phosphonium salts, such as ethyltriphenylphosphonium bromide and tetraphenylphosphonium tetraphenylborate; and the like.

As the curing accelerator used in the present invention, imidazoles, tertiary amines, organic phosphines, and phosphonium salts are preferable. More preferable are imidazoles, tertiary amines, and organic phosphines; even more preferable are 2-methylimidazole, 2-ethyl-4-methylimidazole, 1,2-dimethylimidazole, 1,8-diazabicyclo(5,4,0)undecene-7, and triphenylphosphine; and particularly preferable are 2-methylimidazole, 2-ethyl-4-methylimidazole, and triphenylphosphine.

The amount of the curing accelerator used is not particularly limited, and is preferably 0.01 to 10.0 parts by mass, and more preferably 0.1 to 5 parts by mass, based on 100 parts by mass of the epoxy resin in the epoxy resin composition.

The epoxy resin composition of the present invention may contain an epoxy resin other than the epoxy resin represented by the formula (1) within a range that does not impair the effects of the present invention. Examples include, but are not limited to, bisphenol A epoxy resins, bisphenol F epoxy resins, phenol novolak epoxy resins, cresol novolak epoxy resins, cycloaliphatic epoxy resins, brominated epoxy resins, triglycidyl isocyanurate and hydantoin epoxy resins, both of which are nitrogen-containing ring epoxy resins, hydrogenated bisphenol A epoxy resins, aliphatic epoxy resins, glycidyl ether epoxy resins, bisphenol S epoxy resins, biphenyl epoxy resins, dicyclo epoxy resins, naphthalene epoxy resins, and the like. These epoxy resins may be used singly or in combination of two or more.

When an epoxy resin other than the epoxy resin represented by the formula (1) is mixed, the mixing ratio of the epoxy resin represented by the formula (1) to the epoxy resin other than the epoxy resin represented by the formula (1) is, by mass ratio, for example, 100:0 to 20:80, preferably 100:0 to 30:70, and more preferably 100:0 to 40:60.

The epoxy resin composition of the present invention may contain, if necessary, fillers, curing agents other than liquid phenol-based curing agents, thermoplastic resins, additives, etc., within a range that does not impair the objects and effects of the present invention.

The above fillers can be used singly or in combination of two or more, in consideration of flowability, heat resistance, low thermal expansion properties, mechanical characteristics, hardness, scratch resistance, adhesion, etc. that are required for compositions and cured products. Examples include inorganic compounds, such as silica (specifically crystalline silica, fused silica, spherical fused silica, etc.), titanium oxide, zirconium oxide, zinc oxide, tin oxide, silicon nitride, silicon carbide, boron nitride, calcium carbonate, calcium silicate, potassium titanate, aluminum nitride, indium oxide, alumina, antimony oxide, cerium oxide, magnesium oxide, iron oxide, and tin-doped indium oxide (ITO). Other examples include metals, such as gold, silver, copper, aluminum, nickel, iron, zinc, and stainless steel. Still other examples include minerals, such as montmorillonite, talc, mica, boehmite, kaolin, smectite, zonolite, vermiculite, and sericite. Examples of other fillers include carbon compounds, such as carbon black, acetylene black, Ketjen black, and carbon nanotubes; metal hydroxides, such as aluminum hydroxide and magnesium hydroxide; various types of glass, such as glass beads, glass flakes, and glass balloons; and the like. In terms of the heat resistance and flowability of the epoxy resin composition according to the present invention, inorganic compounds are preferable; in particular, silica and alumina are more preferable. The filler may be used in a powder form, or may be used after being dispersed in a resin.

Examples of curing agents include phenol-based curing agents that are solid at 25° C. at one atmosphere, amine-based curing agents, amide-based curing agents, acid anhydride-based curing agents, mercaptan-based curing agents, isocyanate-based curing agents, active ester-based curing agents, cyanate ester-based curing agents, and the like. The curing agents may be used singly or in combination of two or more because they can be properly used corresponding to the required characteristics.

Examples of thermoplastic resins include polyolefin resins, acrylic resins, phenoxy resins, polyamide resins, polyester resins, polycarbonate resins, polyurethane resins, polyarylate resins, polyphenylene ether resins, polyacetal resins, acid-modified products thereof, and the like. In terms of compatibility with the epoxy resin composition of the present invention and heat resistance, polyolefin resins, acrylic resins, phenoxy resins, polyarylate resins, polyphenylene ether resins, and acid-modified products thereof are preferable; and more preferable among these are polyolefin resins and acid-modified polyolefin resins.

Examples of additives include coupling agents, antioxidants, inorganic fluorescent substances, lubricants, ultraviolet absorbers, heat light stabilizers, antistatic agents, polymerization inhibitors, antifoaming agents, solvents, anti-aging agents, radical inhibitors, adhesion-improving agents, flame retardants, surfactants, storage stability-improving agents, ozone aging inhibitors, thickeners, plasticizers, radiation-blocking agents, nucleating agents, conductivity-imparting agents, phosphorus-based peroxide-decomposing agents, pigments, metal deactivators, physical property-controlling agents, and the like.

Examples of coupling agents include, but are not particularly limited to, γ-aminopropyltrimethoxysilane, γ-aminopropyltriethoxysilane, γ-mercaptopropyltrimethoxysilane, γ-methacryloxypropyltrimethoxysilane, γ-glycidoxypropyltrimethoxysilane, alkoxy oligomer coupling agents (examples of commercial products include KR-516, KR-517, etc., produced by Shin-Etsu Chemical Co., Ltd.), polyfunctional group silane coupling agents (examples of commercial products include X-12-972F, X-12-9815, X-12-9845, X-12-1154, etc., produced by Shin-Etsu Chemical Co., Ltd.), and the like.

The epoxy resin composition of the present invention has relatively low viscosity at 25° C., and has good workability when used as a semiconductor sealing body, a semiconductor sealing material, a liquid sealing material, an underfill material, a potting material, a sealing material, an interlayer insulation film, an adhesive layer, a coverlay film, an electromagnetic shielding film, a printed circuit board material, a composite material, or the like. Specifically, in terms of workability, the viscosity at 25° C. is 0.1 to 1000 Pa·s, preferably 0.1 to 500 Pa·s, and more preferably 1 to 200 Pa·s. The upper or lower limit of this range may be, for example, 150, 100, 90, 80, 70, 60, 50, 40, 30, 20, or 10 Pa·s. For example, this range may be 0.1 to 150 Pa·s or 1 to 100 Pa·s. The viscosity is a value measured using a B-type viscometer at 25° C. at a rotational speed of 20 rpm.

The epoxy resin composition of the present invention has good storage stability at 25° C. and excellent pot life. Specifically, when the specific epoxy resin and the specific phenol-based curing agent are mixed and allowed to stand in a constant-temperature bath at 25° C., the number of days until the viscosity increases twice or more the initial viscosity is preferably 10 days or more.

A cured product can be obtained by curing the epoxy resin composition of the present invention (i.e., a cured product of the epoxy resin composition). The curing method is not particularly limited. For example, a method that cures the composition by heating can be used. The curing temperature is generally room temperature to 250° C. The curing time varies depending on the composition, and can be generally widely set from 30 minutes to 1 week. Moreover, for example, a varnish can be prepared by dissolving the epoxy resin composition in a solvent (e.g., an organic solvent, such as toluene, xylene, methyl ethyl ketone, acetone, cyclohexanone, methylcyclohexane, or cyclohexane) within a range that does not adversely affect the effects of the present invention. Further, a cured product of a desired shape can also be obtained using this varnish. For example, a film-like cured product can be obtained by applying the varnish to a substrate (e.g., copper foil, aluminum foil, or a polyimide film), and heating the applied varnish. The curing temperature is generally room temperature to 200° C. The curing time varies depending on the composition liquid, and can be generally widely set from 30 minutes to 1 week. The present invention also preferably includes such a varnish and a cured product.

In the present specification, the term “comprising” includes “consisting essentially of” and “consisting of.”

### EXAMPLES

The present invention is described in more detail below; however, the present invention is not limited to the following examples.

### Production Example 1 (Production of Epoxy Resin A)

Allyl glycidyl ether (5.9 g), 0.05 g of 2 mass % ethanol solution of hexachloroplatinic acid hexahydrate, and 100 g of toluene were placed in a 200-mL four-necked flask equipped with a stirrer, a thermometer, and a condenser in a nitrogen atmosphere, and the liquid temperature was raised to 70° C. Thereafter, 5.0 g of 1,4-bis(dimethylsilyl)benzene was added dropwise for 15 minutes, and the mixture was then stirred at 90° C. for 4 hours. After the toluene was concentrated, 10.3 g (epoxy equivalent: 211 g/eq) of 1,4-bis[(2,3-epoxypropyloxypropyl)dimethylsilyl]benzene (epoxy resin A) was obtained as a colorless, transparent liquid.

### Production Example 2 (Production of Epoxy Resin B)

1,2-Epoxy-5-hexene (5.0 g), 0.05 g of 2 mass % ethanol solution of hexachloroplatinic acid hexahydrate, and 100 g of toluene were placed in a 200-mL four-necked flask equipped with a stirrer, a thermometer, and a condenser in a nitrogen atmosphere, and the liquid temperature was raised to 70° C. Thereafter, 5.0 g of 1,4-bis(dimethylsilyl)benzene was added dropwise for 15 minutes, and the mixture was then stirred at 90° C. for 5 hours. After the toluene was concentrated, 9.5 g (epoxy equivalent: 195 g/eq) of 1,4-bis[(5,6-epoxyhexyl)dimethylsilyl]benzene (epoxy resin B) was obtained as a colorless, transparent liquid.

### Production Example 3 (Production of Epoxy Resin C)

3,4-Epoxy-1-butene (4.0 g), 0.05 g of 2 mass % ethanol solution of hexachloroplatinic acid hexahydrate, and 100 g of toluene were placed in a 200-mL four-necked flask equipped with a stirrer, a thermometer, and a condenser in a nitrogen atmosphere, and the liquid temperature was raised to 70° C. Thereafter, 5.0 g of 1,4-bis(dimethylsilyl)benzene was added dropwise for 15 minutes, and the mixture was then stirred at 90° C. for 5 hours. After the toluene was concentrated, 8.5 g (epoxy equivalent: 167 g/eq) of 1,4-bis[(3,4-epoxybutyl)dimethylsilyl]benzene (epoxy resin C) was obtained as a colorless, transparent liquid.

### Production Example 4 (Production of Epoxy Resin D)

1,2-Epoxy-4-vinylcyclohexane (6.4 g), 0.05 g of 2 mass % ethanol solution of hexachloroplatinic acid hexahydrate, and 100 g of toluene were placed in a 200-mL four-necked flask equipped with a stirrer, a thermometer, and a condenser in a nitrogen atmosphere, and the liquid temperature was raised to 70° C. Thereafter, 5.0 g of 1,4-bis(dimethylsilyl)benzene was added dropwise for 15 minutes, and the mixture was then stirred at 90° C. for 4 hours. After the toluene was concentrated, 10.8 g (epoxy equivalent: 221 g/eq) of 1,4-bis{[2-(3,4-epoxycyclohexyl)ethyl]dimethylsilyl}benzene (epoxy resin D) was obtained as a colorless, transparent liquid.

### Production Example 5 (Production of Epoxy Resin E)

1,2-Epoxy-4-vinylcyclohexane (4.3 g), 0.05 g of 2 mass % ethanol solution of hexachloroplatinic acid hexahydrate, and 100 g of toluene were placed in a 200-mL four-necked flask equipped with a stirrer, a thermometer, and a condenser in a nitrogen atmosphere, and the liquid temperature was raised to 70° C. Thereafter, 5.0 g of bis[(p-dimethylsilyl)phenyl]ether was added dropwise for 15 minutes, and the mixture was then stirred at 90° C. for 6 hours. After the toluene was concentrated, 8.9 g (epoxy equivalent: 267 g/eq) of 4,4′-bis{[2-(3,4-epoxycyclohexyl)ethyl]dimethylsilyl}diphenyl ether (epoxy resin E) was obtained as a colorless, transparent liquid.

### Production Example 6 (Production of Epoxy Resin F)

1,2-Epoxy-4-vinylcyclohexane (7.4 g), 0.05 g of 2 mass % ethanol solution of hexachloroplatinic acid hexahydrate, and 100 g of toluene were placed in a 200-mL four-necked flask equipped with a stirrer, a thermometer, and a condenser in a nitrogen atmosphere, and the liquid temperature was raised to 70° C. Thereafter, 5.0 g of 1,3,5-tris(dimethylsilyl)benzene was added dropwise for 15 minutes, and the mixture was then stirred at 90° C. for 6 hours. After the toluene was concentrated, 11.8 g (epoxy equivalent: 208 g/eq) of 1,3,5-tris{[2-(3,4-epoxycyclohexyl)ethyl]dimethylsilyl}benzene (epoxy resin F) was obtained as a colorless, transparent liquid.

### Examples 1 to 9 and Comparative Examples 1 to 4

First, the raw materials used in the present Examples and Comparative Examples are collectively shown below.
Epoxy resin G: bisphenol F epoxy resin (Grade 806, produced by Mitsubishi Chemical Corporation) (epoxy equivalent: 175 g/eq)
Epoxy resin H: cycloaliphatic epoxy resin (Celloxide 2021P; general name: 3′,4′-epoxycyclohexylmethyl 3,4-epoxycyclohexane carboxylate, produced by Daicel Corporation) (epoxy equivalent: 137 g/eq)
Epoxy resin I: dicyclopentadiene type epoxy resin (HP-7200, produced by DIC) (epoxy equivalent: 268 g/eq)
Liquid phenol-based curing agent A: allylated phenol novolak resin (MEH-8000H, produced by Meiwa Plastic Industries, Ltd.)
Liquid phenol-based curing agent B: alkylated phenol novolak resin (ELPC75, produced by Gun Ei Chemical Industry Co., Ltd.)
Liquid phenol-based curing agent C: allylated phenol resol resin (ELR, produced by Gun Ei Chemical Industry Co., Ltd.)
Solid phenol-based curing agent: phenol novolak resin (TD-2131, produced by DIC)
Curing accelerator A: 2-methylimidazole (2MZ-H, produced by Shikoku Chemicals Corporation)
Curing accelerator B: triphenylphosphine (TPP, produced by Tokyo Chemical Industry Co., Ltd.)
Filler: fused silica (SE-E2, produced by Admatechs Co., Ltd.)

According to DIC Technical Review No. 11/2005, pp. 21-25, epoxy resin I (HP-7200) is a resin represented by the following formula:

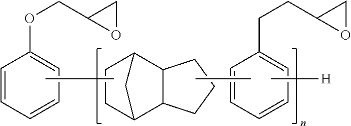

According to JP2012-025918A and JP2012-162664A, liquid phenol-based curing agent A (MEH-8000H) is a resin represented by the following formula:

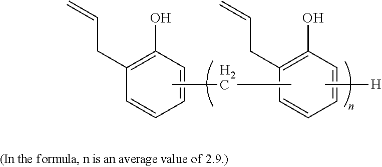

According to the website of Gun Ei Chemical Industry Co., Ltd., liquid phenol-based curing agent B (ELPC75) is a resin represented by the following formula, and its viscosity is 24 Pa·s.

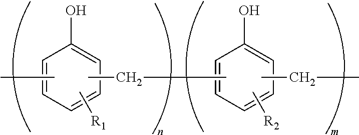

According to the website of Gun Ei Chemical Industry Co., Ltd., liquid phenol-based curing agent C (ELR) is a resin represented by the following formula, and its viscosity is 3000 P (i.e., 300 Pa·s).

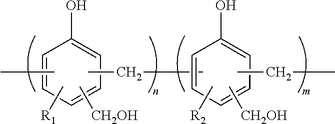

According to WO2018/131567, the solid phenol-based curing agent (TD-2131) is a resin represented by the following formula:

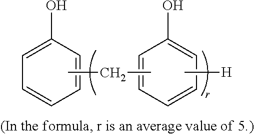

### Examples 1 to 10 and Comparative Examples 1 to 3

Components in amounts (parts by mass) shown in Table 1 were each weighed in a cup, and mixed using a rotation/revolution mixer (ARE-310, produced by Thinky Corporation) at room temperature (25° C.) at 2000 rpm for 5 minutes. Then, defoaming was performed at room temperature (25° C.) at 2200 rpm for 5 minutes, thereby preparing epoxy resin compositions.

### Comparative Example 4

The solid phenol-based curing agent (47 parts by mass) was added to 47 parts by mass of acetone, and dissolved by stirring with a magnetic stirrer at room temperature (25° C.) for 30 minutes. Epoxy resin D (100 parts by mass) and curing accelerator B were added thereto, and the mixture was uniformly mixed. Thereafter, degassing was sufficiently performed to thereby prepare a varnish of an epoxy resin composition.

In the Examples and Comparative Examples, the ratio of the equivalent of reactive functional groups (hydroxyl groups) in the curing agent (liquid phenol-based curing agent or solid phenol-based curing agent) to the equivalent of epoxy groups in the epoxy resin was adjusted to 50:50.

The epoxy resin compositions obtained in the Examples and Comparative Examples were evaluated for the following items. The evaluation results are also shown in Table 1.

### Viscosity

The viscosity of the epoxy resin compositions obtained in Examples 1 to 10 and Comparative Examples 1 to 3 was measured using a B-type viscometer (produced by Eko Instruments Co., Ltd.) at 25° C. at a rotational speed of 20 rpm.

### Pot Life

The epoxy resin compositions obtained in Examples 1 to 10 and Comparative Examples 1 to 3 were allowed to stand in a constant-temperature bath at 25° C. Then, the number of days until the viscosity increased twice or more the initial viscosity was measured.

### Tensile Shear Adhesion Strength to Copper Plate

The epoxy resin compositions obtained in Examples 1 to 10 and Comparative Examples 1 to 4 were each applied to an oxygen-free copper plate (JIS C1020P) (size: 2×25×100 mm) so that the adhesive part had a rectangular shape (12.5×25 mm). Another oxygen-free copper plate was bonded thereto, and the resultant was cured by heating at 100° C. for 1 hour, 120° C. for 2 hours, 150° C. for 2 hours, 180° C. for 2 hours, and 200° C. for 2 hours, thereby preparing tensile shear adhesion test pieces.

The obtained adhesion test pieces were each subjected to a tensile shear adhesion test using a tensile tester (AGS-X, produced by Shimadzu Corp.) with a gripper distance of 100 mm at a test speed of 5 mm/min. The tensile shear adhesion strength was calculated from the measured maximum rupture strength and the adhesion area.

### Relative Dielectric Constant and Dielectric Loss Tangent

The epoxy resin compositions obtained in Examples 1 to 10 and Comparative Examples 1 to 4 were each poured into a resin mold (thickness: 3 mm), and cured by heating at 100° C. for 1 hour, 120° C. for 2 hours, 150° C. for 2 hours, 180° C. for 2 hours, and 200° C. for 2 hours. Subsequently, the cured products were each cut into size of 3 mm width×80 mm length×1 mm thickness, thereby preparing test pieces for dielectric constant measurement.

The relative dielectric constant (1 GHz) and dielectric loss tangent (1 GHz) of each of the obtained test pieces were measured using a dielectric constant measuring device (Impedance Analyzer, produced by AET, Inc.).

TABLE 1

| | Example | Example | Example | Example | Example | Example | Example | Example | Example | Example | Comparative | Comparative | Comparative | Comparative |
|---|---|---|---|---|---|---|---|---|---|---|---|---|---|---|
| | 1 | 2 | 3 | 4 | 5 | 6 | 7 | 8 | 9 | 10 | Example 1 | Example 2 | Example 3 | Example 4 |
| Epoxy resin A | 100 | 0 | 0 | 0 | 0 | 0 | 0 | 0 | 0 | 0 | 0 | 0 | 0 | 0 |
| Epoxy resin B | 0 | 100 | 0 | 0 | 0 | 0 | 100 | 0 | 100 | 0 | 0 | 0 | 0 | 0 |
| Epoxy resin C | 0 | 0 | 100 | 0 | 0 | 0 | 0 | 0 | 0 | 0 | 0 | 0 | 0 | 0 |
| Epoxy resin D | 0 | 0 | 0 | 100 | 0 | 0 | 0 | 100 | 0 | 100 | 0 | 0 | 0 | 100 |
| Epoxy resin E | 0 | 0 | 0 | 0 | 100 | 0 | 0 | 0 | 0 | 0 | 0 | 0 | 0 | 0 |
| Epoxy resin F | 0 | 0 | 0 | 0 | 0 | 100 | 0 | 0 | 0 | 0 | 0 | 0 | 0 | 0 |
| Epoxy resin G | 0 | 0 | 0 | 0 | 0 | 0 | 0 | 0 | 0 | 0 | 100 | 0 | 0 | 0 |
| Epoxy resin H | 0 | 0 | 0 | 0 | 0 | 0 | 0 | 0 | 0 | 0 | 0 | 100 | 0 | 0 |
| Epoxy resin I | 0 | 0 | 0 | 0 | 0 | 0 | 0 | 0 | 0 | 0 | 0 | 0 | 100 | 0 |
| Liquid phenol-based | 67 | 72 | 92 | 64 | 53 | 24 | 72 | 0 | 0 | 64 | 81 | 103 | 54 | 0 |
| curing agent A | | | | | | | | | | | | | | |
| Liquid phenol-based | 0 | 0 | 0 | 0 | 0 | 0 | 0 | 93 | 0 | 0 | 0 | 0 | 0 | 0 |
| curing agent B | | | | | | | | | | | | | | |
| Liquid phenol-based | 0 | 0 | 0 | 0 | 0 | 0 | 0 | 0 | 70 | 0 | 0 | 0 | 0 | 0 |
| curing agent C | | | | | | | | | | | | | | |
| Solid phenol-based | 0 | 0 | 0 | 0 | 0 | 0 | 0 | 0 | 0 | 0 | 0 | 0 | 0 | 47 |
| curing agent | | | | | | | | | | | | | | |
| Curing accelerator A | 1 | 1 | 1 | 1 | 1 | 1 | 0 | 1 | 1 | 1 | 1 | 1 | 1 | 0 |
| Curing accelerator B | 0 | 0 | 0 | 0 | 0 | 0 | 1 | 0 | 0 | 0 | 0 | 0 | 0 | 1 |
| Filler | 0 | 0 | 0 | 0 | 0 | 0 | 0 | 0 | 0 | 165 | 0 | 0 | 0 | 0 |
| Viscosity (Pa · s) | 3.0 | 5.2 | 3.1 | 9.0 | 11.0 | 15.8 | 4.0 | 10.2 | 199.8 | 35.0 | 8.5 | 3.1 | 326.0 | — |
| Pot life (days) | >10 | >10 | >10 | >10 | >10 | >10 | >10 | >10 | >10 | >10 | 2 | >10 | 2 | — |
| Tensile shear (MPa) | 15.0 | 16.1 | 15.6 | 18.5 | 18.0 | 19.0 | 18.5 | 15.1 | 19.2 | 20.0 | 19.7 | 4.0 | 6.2 | 9.1 |
| Relative dielectric | 2.8 | 2.7 | 2.7 | 2.6 | 2.7 | 2.8 | 2.7 | 2.6 | 2.8 | 3.1 | 3.2 | 3.3 | 3.0 | 2.9 |
| constant (1 GHz) | | | | | | | | | | | | | | |
| Dielectric loss tangent | 0.014 | 0.012 | 0.011 | 0.011 | 0.012 | 0.014 | 0.012 | 0.012 | 0.015 | 0.009 | 0.023 | 0.032 | 0.019 | 0.011 |
| (1 GHz) | | | | | | | | | | | | | | |

*solid at 25° C., unmeasurable

The epoxy resin compositions described in Examples 1 to 10 exhibited equivalent or superior adhesion, and superior storage stability, relative dielectric constant, and dielectric loss tangent, compared with the epoxy resin compositions of Comparative Examples 1 to 3. Further, they were liquid at 25° C. and showed lower viscosity, compared with the epoxy resin composition of Comparative Example 4.

1. An epoxy resin composition comprising an epoxy resin and a phenol-based curing agent that is liquid at 25° C., the epoxy resin being at least one member selected from the group consisting of:
an epoxy resin represented by the formula (1-iia): 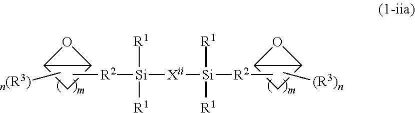
wherein Xⁱⁱ is a divalent group obtained by removing two hydrogen atoms from a saturated hydrocarbon ring or an unsaturated hydrocarbon ring, or from rings having a structure in which 2 to 6 saturated hydrocarbon rings and/or unsaturated hydrocarbon rings are condensed; or a divalent group represented by the formula (2^{g}-iia): 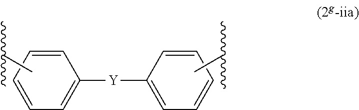
wherein Y is a bond, a C₁₋₆ alkylene group that may be substituted with a C₁₋₄ alkyl group, an oxygen atom (—O—), a sulfur atom (—S—), —SO—, or —SO₂—;
R¹ is the same or different, and is a C₁₋₁₈ alkyl group, a C₂₋₉ alkenyl group, a cycloalkyl group, an aryl group, or an aralkyl group, wherein one or more carbon atoms of these groups may be replaced by at least one atom selected from the group consisting of an oxygen atom and a nitrogen atom;
R² is the same or different, and is a C₁₋₁₈ alkylene group, wherein one or more carbon atoms of this group other than a carbon atom directly bonded to a silicon atom may be replaced by at least one atom selected from the group consisting of an oxygen atom and a nitrogen atom;
R³ is the same or different, and is a C₁₋₁₈ alkyl group, a C₂₋₉ alkenyl group, a cycloalkyl group, an aryl group, or an aralkyl group, wherein one or more carbon atoms of these groups may be replaced by at least one atom selected from the group consisting of an oxygen atom and a nitrogen atom;
m is an integer of 0 to 6; and
n is an integer of 0 to 3;
an epoxy resin represented by the formula (1-iiia): 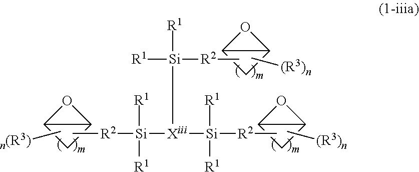
wherein Xⁱⁱⁱ is a trivalent group obtained by removing three hydrogen atoms from a saturated hydrocarbon ring or an unsaturated hydrocarbon ring, or from rings having a structure in which 2 to 6 saturated hydrocarbon rings and/or unsaturated hydrocarbon rings are condensed; or a trivalent group represented by the formula (2^{g}-iiia): 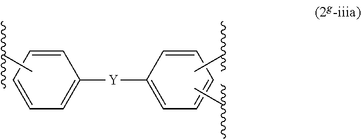
wherein Y is as defined above; and
R¹, R², R³, m, and n are as defined above; and
an epoxy resin represented by the formula (1-iva): 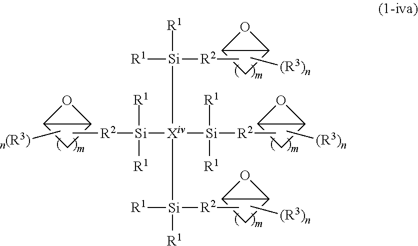
wherein X^{iv} is a tetravalent group obtained by removing four hydrogen atoms from a saturated hydrocarbon ring or an unsaturated hydrocarbon ring, or from rings having a structure in which 2 to 6 saturated hydrocarbon rings and/or unsaturated hydrocarbon rings are condensed; or a tetravalent group represented by the formula (2^{g}): 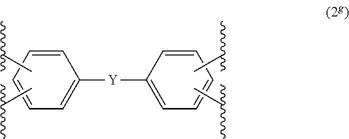
wherein Y is as defined above; and
R¹, R², R³, m, and n are as defined above.

2. The epoxy resin composition according to claim 1, wherein the saturated hydrocarbon ring is a C₄₋₈ saturated hydrocarbon ring, and the unsaturated hydrocarbon ring is a C₄₋₈ unsaturated hydrocarbon ring.

3. The epoxy resin composition according to claim 1, wherein the epoxy resin is at least one member selected from the group consisting of:
an epoxy resin represented by the formula (1-IIa): 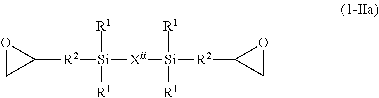
wherein R¹, R², and Xⁱⁱ are as defined above;
an epoxy resin represented by the formula (1-IIb): 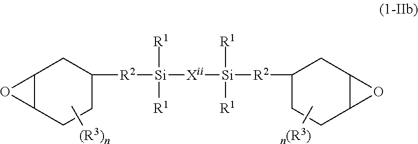
wherein R¹, R², R³, Xⁱⁱ, and n are as defined above; and
an epoxy resin represented by the formula (1-IIIa): 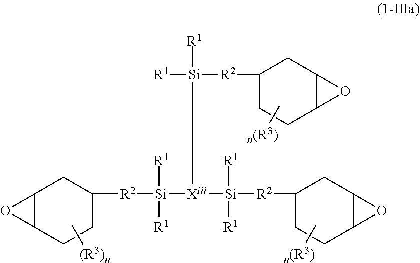
wherein R¹, R², R³, Xⁱⁱⁱ, and n are as defined above.

4. The epoxy resin composition according claim 3, wherein the epoxy resin represented by the formula (1-IIa) is an epoxy resin wherein Xⁱⁱ is a 1,4-phenylene group or a group represented by the formula (2^{g}-iia′): 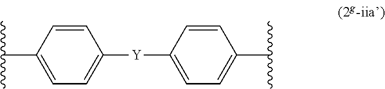
wherein Y is as defined above,
R¹ is the same or different, and is a C₁₋₃ alkyl group, and R² is the same or different, and is a C₂₋₆ alkylene group, (*)—(CH₂)₂—O—CH₂—, (*)—(CH₂)₃—O—CH₂—, (*)—(CH₂)₃—O—(CH₂)₂—, or (*)—(CH₂)₅—O—(CH₂)₄—, provided that (*) represents the side of R² binding to the silicon atom;
the epoxy resin represented by the formula (1-IIb) is an epoxy resin wherein Xⁱⁱ is a 1,4-phenylene group or a group represented by the formula (2^{g}-iia′): 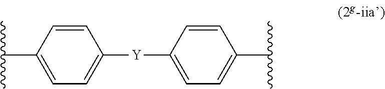
wherein Y is as defined above,
R¹ is the same or different, and is a C₁₋₃ alkyl group, both n is 0, and R² is the same or different, and is a C₂₋₆ alkylene group; and
the epoxy resin represented by the formula (1-IIIa) is an epoxy resin wherein Xⁱⁱⁱ is 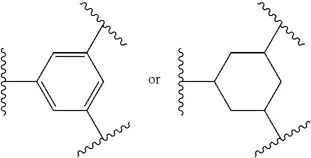 [SMILES: *c1cc(*)cc(*)c1 ; *C1CC(*)CC(*)C1]
or a group represented by the formula (2^{g}-iiia′): 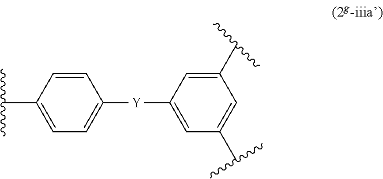
wherein Y is as defined above,
R¹ is the same or different, and is a C₁₋₃ alkyl group, both n is 0, and R² is the same or different, and is a C₂₋₆ alkylene group.

5. The epoxy resin composition according claim 1, wherein the phenol-based curing agent that is liquid at 25° C. comprises at least one member selected from the group consisting of liquid allylphenol resins, liquid propenylphenol resins, and liquid alkylphenol resins.

6. The epoxy resin composition according any claim 1, wherein the phenol-based curing agent that is liquid at 25° C. comprises at least one member selected from the group consisting of resins represented by the formula (7): 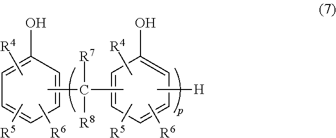
wherein R⁴ to R⁶ are the same or different, and each is a hydrogen atom, a C₂₋₉ alkenyl group, a C₁₋₁₈ alkyl group, or a C₁₋₉ alkylol group; R⁷ and R⁸ are the same or different, and each is a hydrogen atom or a C₁₋₄ alkyl group; and p is an average value of 0 to 6; provided that not all of R⁴ are hydrogen atoms, not all of R⁵ are hydrogen atoms, and not all of R⁶ are hydrogen atom.

7. The epoxy resin composition according claim 1, further comprising at least one of silica and alumina as an inorganic filler.

8. A varnish comprising the epoxy resin composition according to claim 1 and an organic solvent.

9. A cured product of the epoxy resin composition according to claim 1.

10. A semiconductor sealing body, a semiconductor sealing material, a liquid sealing material, an underfill material, a potting material, a sealing material, an interlayer insulation film, an adhesive layer, a coverlay film, an electromagnetic shielding film, a printed circuit board material, or a composite material, each of which comprises the epoxy resin composition according to claim 1.

11. The epoxy resin composition according to claim 1, for a semiconductor sealing body, a semiconductor sealing material, a liquid sealing material, an underfill material, a potting material, a sealing material, an interlayer insulation film, an adhesive layer, a coverlay film, an electromagnetic shielding film, a printed circuit board material, or a composite material.

12. Use of the epoxy resin composition according to claim 1, for producing a semiconductor sealing body, a semiconductor sealing material, a liquid sealing material, an underfill material, a potting material, a sealing material, an interlayer insulation film, an adhesive layer, a coverlay film, an electromagnetic shielding film, a printed circuit board material, or a composite material.
